(19) United States
(12) Patent Application Publication
(10) Pub. No.: US 2026/0370379 A1
(43) Pub. Date: Nov. 19, 2026

(54) SYSTEM FRAME NUMBER ENCODING TECHNIQUES FOR SOFT COMBINING

(71) Applicant: QUALCOMM Incorporated, San Diego, CA (US)

(72) Inventors: Kirill IVANOV, La Jolla, CA (US); Wei YANG, San Diego, CA (US); Jing SUN, San Diego, CA (US); Yan ZHOU, San Diego, CA (US); Jing JIANG, San Diego, CA (US)

(21) Appl. No.: 19/212,308

(22) Filed: May 19, 2025

(51) Int. Cl. H04L 1/00; H04W 72/30

(52) U.S. Cl. CPC H04L 1/0041; H04W 72/30

(57) ABSTRACT

Certain aspects of the present disclosure provide techniques for encoding a system frame number to enable soft combining. An example method performed by a network entity includes obtaining a first physical broadcast channel (PBCH) payload including a first encoded system frame number (SFN) that indicates a first SFN of a set of SFNs, wherein the first PBCH payload is obtained based on a fixed permutation, applying a transform function to the first PBCH payload to convert the first PBCH payload to a transform domain, and transmitting the first PBCH payload after applying the transform function to the first PBCH payload.

### BACKGROUND

### Field of the Disclosure

Aspects of the present disclosure relate to wireless communications, and more particularly, to techniques for encoding a system frame number to enable soft combining.

### Description of Related Art

Wireless communications systems are widely deployed to provide various telecommunication services such as telephony, video, data, messaging, broadcasts, or other similar types of services. These wireless communications systems may employ multiple-access technologies capable of supporting communications with multiple users by sharing available wireless communications system resources with those users.

Although wireless communications systems have made great technological advancements over many years, challenges still exist. For example, complex and dynamic environments can still attenuate or block signals between wireless transmitters and wireless receivers. Accordingly, there is a continuous desire to improve the technical performance of wireless communications systems, including, for example: improving speed and data carrying capacity of communications, improving efficiency of the use of shared communications mediums, reducing power used by transmitters and receivers while performing communications, improving reliability of wireless communications, avoiding redundant transmissions and/or receptions and related processing, improving the coverage area of wireless communications, increasing the number and types of devices that can access wireless communications systems, increasing the ability for different types of devices to intercommunicate, increasing the number and type of wireless communications mediums available for use, and the like. Consequently, there exists a need for further improvements in wireless communications systems to overcome the aforementioned technical challenges and others.

### SUMMARY

One aspect provides a method for wireless communication by a network entity. The method includes obtaining a first physical broadcast channel (PBCH) payload including a first encoded system frame number (SFN) that indicates a first SFN of a set of SFNs, wherein the first PBCH payload is obtained based on a fixed permutation; applying a transform function to the first PBCH payload to convert the first PBCH payload to a transform domain; and transmitting the first PBCH payload after applying the transform function to the first PBCH payload.

Another aspect provides a method for wireless communication by a user equipment (UE). The method includes receiving a first physical broadcast channel (PBCH) payload including a first encoded system frame number (SFN) that indicates a first SFN of a set of SFNs, wherein the first PBCH payload is based on a fixed permutation and a transform function; receiving a second PBCH payload including a second encoded SFN that indicates a second SFN of the set of SFNs, wherein the second PBCH payload is based on the first PBCH payload including the first encoded SFN, the fixed permutation, and the transform function; and performing a soft combining procedure to detect the first encoded SFN based on the first PBCH payload and the second PBCH payload.

Other aspects provide: an apparatus operable, configured, or otherwise adapted to perform any one or more of the aforementioned methods and/or those described elsewhere herein; a non-transitory, computer-readable media comprising instructions that, when executed by one or more processors of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

The following description and the appended figures set forth certain features for purposes of illustration.

### BRIEF DESCRIPTION OF DRAWINGS

The appended figures depict certain features of the various aspects described herein and are not to be considered limiting of the scope of this disclosure.

FIG. 1 depicts an example wireless communications network.

FIG. 2 depicts an example disaggregated base station architecture.

FIG. 3 depicts aspects of an example base station and an example user equipment.

FIGS. 4A, 4B, 4C, and 4D depict various example aspects of data structures for a wireless communications network.

FIGS. 5A and 5B include simplified network-side and UE-side process flows, respectively, including operations illustrating encoding techniques and modification functions that may be used to enable soft combining of physical broadcast channel (PBCH) payloads including time-varying information.

FIG. 5C illustrates a simplified network-side process flow including operations for enabling soft combining of PBCH payloads when a system frame number (SFN) is encoded as a one-hot complex vector.

FIG. 6 depicts a method for wireless communications.

FIG. 7 depicts a method for wireless communications.

FIG. 8 depicts aspects of an example communications device.

FIG. 9 depicts aspects of an example communications device.

### DETAILED DESCRIPTION

Aspects of the present disclosure provide apparatuses, methods, processing systems, and computer-readable mediums for encoding a system frame number to enable soft combining.

For example, in certain wireless communication networks, a PBCH may be periodically transmitted by a network entity, such as a base station, to all user equipments (UEs) within a cell. The PBCH carries critical system information necessary for UEs to access and connect to the network. The payload transmitted over the PBCH may include both dynamic, time-varying information and static or semi-static information. For example, the time-varying information may include parameters such as a system frame number (SFN) and a beam index, which may change from transmission to transmission. Static or semi-static information may include parameters such as a half-frame indicator, cell barring information, and cell reselection information, which may remain constant across multiple transmissions.

UEs located at the edge of a cell may experience degraded link conditions, making it difficult to decode the PBCH payload from a single transmission. To improve decoding performance, a UE may apply a soft combining technique, wherein coded bit log likelihood ratio (LLR) values from the current PBCH transmission are combined with coded bit LLR values from one or more previous PBCH transmissions, thereby enhancing the effective signal quality.

Soft combining is most effective when the payload content remains consistent across transmissions. However, when certain parameters, such as the SFN, vary between transmissions, reliable soft combining becomes more challenging. This is because the UE is generally unaware of the SFN value carried by each PBCH transmission, and therefore also unaware of the absolute timing information conveyed by the SFN. Without accurate knowledge of the content of the SFN, any attempt to soft-combine multiple PBCH transmissions or payloads may introduce errors rather than improve decoding performance, thereby negating the benefits of combining and potentially increasing the UE's power consumption.

Accordingly, aspects of the present disclosure provide techniques for enabling a UE to use soft combining to detect and decode an SFN included within a PBCH payload, even when the UE may not know the contents of the SFN or the absolute timing information conveyed thereby. For example, while the UE may not know the contents of the SFN or the absolute timing information conveyed thereby, the UE may know a relative timing between two consecutive PBCH payloads carrying consecutive SFNs and may also know how much the content of the SFN increments between the two consecutive PBCH payloads, which may be used to enable soft combining.

For example, the techniques presented herein include techniques for encoding SFNs in a particular manner and applying certain modification functions to consecutive PBCH payloads carrying these encoded SFNs, including a fixed permutation and transform function, which may enable the UE to use soft combining to combine the consecutive PBCH payloads to detect and decode an SFN while only knowing the time difference or relative timing between the consecutive PBCH payloads. Accordingly, the techniques presented herein may allow the UE to reliably soft-combine multiple PBCH transmissions and accurately recover the SFN, thereby improving decoding performance, reducing power consumption, and enabling proper frame synchronization with the wireless network.

### Introduction to Wireless Communications Networks

The techniques and methods described herein may be used for various wireless communications networks. While aspects may be described herein using terminology commonly associated with 3G, 4G, and/or 5G wireless technologies, aspects of the present disclosure may likewise be applicable to other communications systems and standards not explicitly mentioned herein.

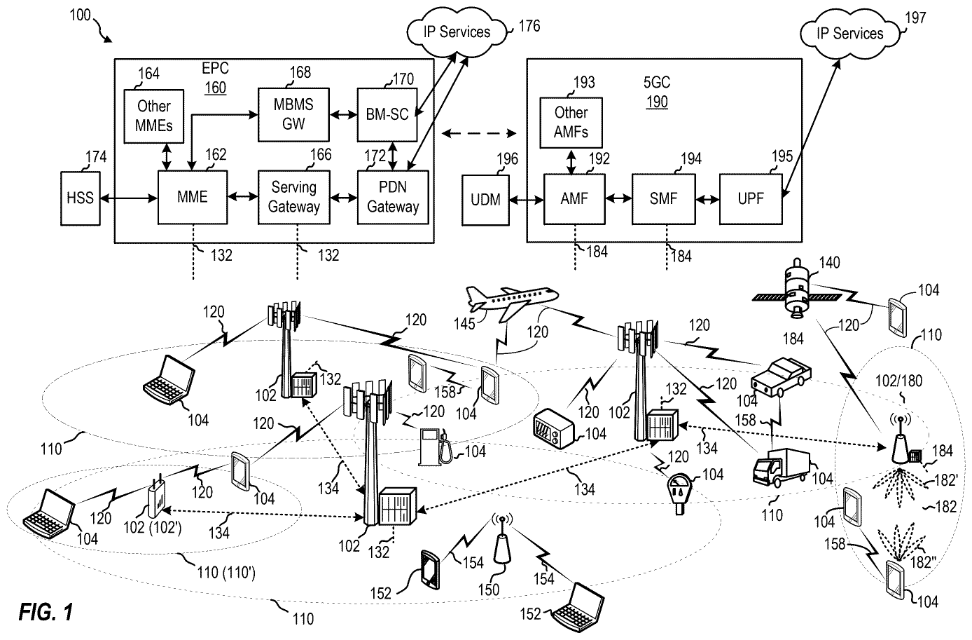

FIG. 1 depicts an example of a wireless communications network 100, in which aspects described herein may be implemented.

Generally, wireless communications network 100 includes various network entities (alternatively, network elements or network nodes). A network entity is generally a communications device and/or a communications function performed by a communications device (e.g., a user equipment (UE), a base station (BS), a component of a BS, a server, etc.). For example, various functions of a network as well as various devices associated with and interacting with a network may be considered network entities. Further, wireless communications network 100 includes terrestrial aspects, such as ground-based network entities (e.g., BSs 102), and non-terrestrial aspects, such as satellite 140 and aircraft 145, which may include network entities on-board (e.g., one or more BSs) capable of communicating with other network elements (e.g., terrestrial BSs) and user equipments.

In the depicted example, wireless communications network 100 includes BSs 102, UEs 104, and one or more core networks, such as an Evolved Packet Core (EPC) 160 and 5G Core (5GC) network 190, which interoperate to provide communications services over various communications links, including wired and wireless links.

FIG. 1 depicts various example UEs 104, which may more generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. UEs 104 may also be referred to more generally as a mobile device, a wireless device, a wireless communications device, a station, a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and others.

BSs 102 wirelessly communicate with (e.g., transmit signals to or receive signals from) UEs 104 via communications links 120. The communications links 120 between BSs 102 and UEs 104 may include uplink (UL) (also referred to as reverse link) transmissions from a UE 104 to a BS 102 and/or downlink (DL) (also referred to as forward link) transmissions from a BS 102 to a UE 104. The communications links 120 may use multiple-input and multiple-output (MIMO) antenna technology, including spatial multiplexing, beamforming, and/or transmit diversity in various aspects.

BSs 102 may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and/or others. Each of BSs 102 may provide communications coverage for a respective geographic coverage area 110, which may sometimes be referred to as a cell, and which may overlap in some cases (e.g., small cell 102′ may have a coverage area 110′ that overlaps the coverage area 110 of a macro cell). A BS may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

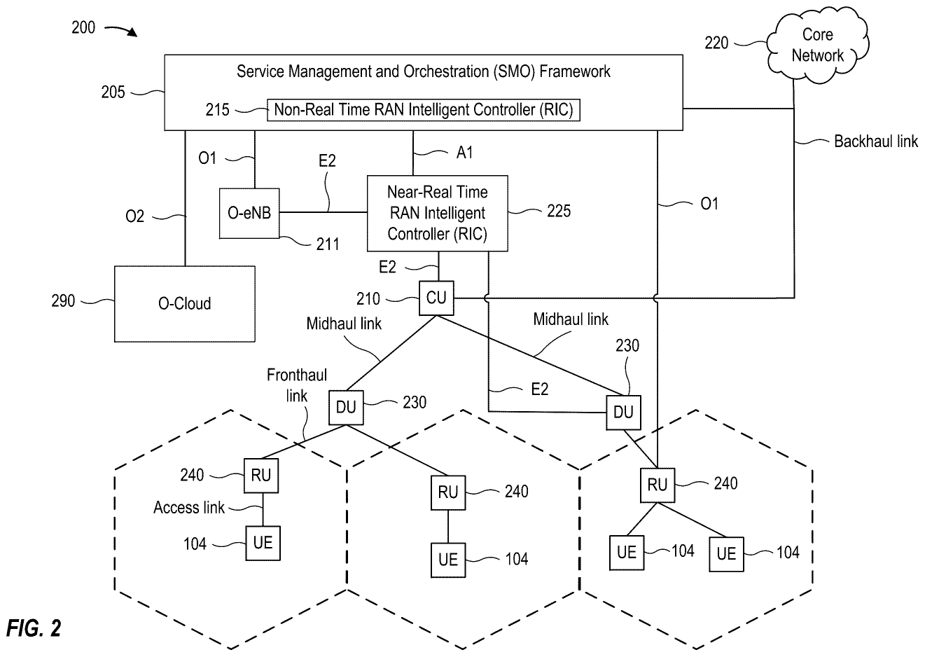

While BSs 102 are depicted in various aspects as unitary communications devices, BSs 102 may be implemented in various configurations. For example, one or more components of a base station may be disaggregated, including a central unit (CU), one or more distributed units (DUs), one or more radio units (RUs), a Near-Real Time (Near-RT) RAN Intelligent Controller (RIC), or a Non-Real Time (Non-RT) RIC, to name a few examples. In another example, various aspects of a base station may be virtualized. More generally, a base station (e.g., BS 102) may include components that are located at a single physical location or components located at various physical locations. In examples in which a base station includes components that are located at various physical locations, the various components may each perform functions such that, collectively, the various components achieve functionality that is similar to a base station that is located at a single physical location. In some aspects, a base station including components that are located at various physical locations may be referred to as a disaggregated radio access network architecture, such as an Open RAN (O-RAN) or Virtualized RAN (VRAN) architecture. FIG. 2 depicts and describes an example disaggregated base station architecture.

Different BSs 102 within wireless communications network 100 may also be configured to support different radio access technologies, such as 3G, 4G, and/or 5G. For example, BSs 102 configured for 4G LTE (collectively referred to as Evolved Universal Mobile Telecommunications System (UMTS) Terrestrial Radio Access Network (E-UTRAN)) may interface with the EPC 160 through first backhaul links 132 (e.g., an S1 interface). BSs 102 configured for 5G (e.g., 5G NR or Next Generation RAN (NG-RAN)) may interface with 5GC 190 through second backhaul links 184. BSs 102 may communicate directly or indirectly (e.g., through the EPC 160 or 5GC 190) with each other over third backhaul links 134 (e.g., X2 interface), which may be wired or wireless.

Wireless communications network 100 may subdivide the electromagnetic spectrum into various classes, bands, channels, or other features. In some aspects, the subdivision is provided based on wavelength and frequency, where frequency may also be referred to as a carrier, a subcarrier, a frequency channel, a tone, or a subband. For example, 3GPP currently defines Frequency Range 1 (FR1) as including 410 MHz-7125 MHz, which is often referred to (interchangeably) as “Sub-6 GHz”. Similarly, 3GPP currently defines Frequency Range 2 (FR2) as including 24,250 MHz-71,000 MHZ, which is sometimes referred to (interchangeably) as a “millimeter wave” (“mmW” or “mmWave”). In some cases, FR2 may be further defined in terms of sub-ranges, such as a first sub-range FR2-1 including 24,250 MHz-52,600 MHz and a second sub-range FR2-2 including 52,600 MHz-71,000 MHz. A base station configured to communicate using mm Wave/near mm Wave radio frequency bands (e.g., a mmWave base station such as BS 180) may utilize beamforming (e.g., 182) with a UE (e.g., 104) to improve path loss and range.

The communications links 120 between BSs 102 and, for example, UEs 104, may be through one or more carriers, which may have different bandwidths (e.g., 5, 10, 15, 20, 100, 400, and/or other MHz), and which may be aggregated in various aspects. Carriers may or may not be adjacent to each other. Allocation of carriers may be asymmetric with respect to DL and UL (e.g., more or fewer carriers may be allocated for DL than for UL).

Communications using higher frequency bands may have higher path loss and a shorter range compared to lower frequency communications. Accordingly, certain base stations (e.g., 180 in FIG. 1) may utilize beamforming 182 with a UE 104 to improve path loss and range. For example, BS 180 and the UE 104 may each include a plurality of antennas, such as antenna elements, antenna panels, and/or antenna arrays to facilitate the beamforming. In some cases, BS 180 may transmit a beamformed signal to UE 104 in one or more transmit directions 182′. UE 104 may receive the beamformed signal from the BS 180 in one or more receive directions 182″. UE 104 may also transmit a beamformed signal to the BS 180 in one or more transmit directions 182″. BS 180 may also receive the beamformed signal from UE 104 in one or more receive directions 182′. BS 180 and UE 104 may then perform beam training to determine the best receive and transmit directions for each of BS 180 and UE 104. Notably, the transmit and receive directions for BS 180 may or may not be the same. Similarly, the transmit and receive directions for UE 104 may or may not be the same.

Wireless communications network 100 further includes a Wi-Fi AP 150 in communication with Wi-Fi stations (STAs) 152 via communications links 154 in, for example, a 2.4 GHz and/or 5 GHz unlicensed frequency spectrum.

Certain UEs 104 may communicate with each other using device-to-device (D2D) communications link 158. D2D communications link 158 may use one or more sidelink channels, such as a physical sidelink broadcast channel (PSBCH), a physical sidelink discovery channel (PSDCH), a physical sidelink shared channel (PSSCH), a physical sidelink control channel (PSCCH), and/or a physical sidelink feedback channel (PSFCH).

EPC 160 may include various functional components, including: a Mobility Management Entity (MME) 162, other MMEs 164, a Serving Gateway 166, a Multimedia Broadcast Multicast Service (MBMS) Gateway 168, a Broadcast Multicast Service Center (BM-SC) 170, and/or a Packet Data Network (PDN) Gateway 172, such as in the depicted example. MME 162 may be in communication with a Home Subscriber Server (HSS) 174. MME 162 is the control node that processes the signaling between the UEs 104 and the EPC 160. Generally, MME 162 provides bearer and connection management.

Generally, user Internet protocol (IP) packets are transferred through Serving Gateway 166, which itself is connected to PDN Gateway 172. PDN Gateway 172 provides UE IP address allocation as well as other functions. PDN Gateway 172 and the BM-SC 170 are connected to IP Services 176, which may include, for example, the Internet, an intranet, an IP Multimedia Subsystem (IMS), a Packet Switched (PS) streaming service, and/or other IP services.

BM-SC 170 may provide functions for MBMS user service provisioning and delivery. BM-SC 170 may serve as an entry point for content provider MBMS transmission, may be used to authorize and initiate MBMS Bearer Services within a public land mobile network (PLMN), and/or may be used to schedule MBMS transmissions. MBMS Gateway 168 may be used to distribute MBMS traffic to the BSs 102 belonging to a Multicast Broadcast Single Frequency Network (MBSFN) area broadcasting a particular service, and/or may be responsible for session management (start/stop) and for collecting eMBMS related charging information.

5GC 190 may include various functional components, including: an Access and Mobility Management Function (AMF) 192, other AMFs 193, a Session Management Function (SMF) 194, and a User Plane Function (UPF) 195. AMF 192 may be in communication with Unified Data Management (UDM) 196.

AMF 192 is a control node that processes signaling between UEs 104 and 5GC 190. AMF 192 provides, for example, quality of service (QoS) flow and session management.

Internet protocol (IP) packets are transferred through UPF 195, which is connected to the IP Services 197, and which provides UE IP address allocation as well as other functions for 5GC 190. IP Services 197 may include, for example, the Internet, an intranet, an IMS, a PS streaming service, and/or other IP services.

In various aspects, a network entity or network node can be implemented as an aggregated base station, as a disaggregated base station, a component of a base station, an integrated access and backhaul (IAB) node, a relay node, a sidelink node, to name a few examples.

FIG. 2 depicts an example disaggregated base station 200 architecture. The disaggregated base station 200 architecture may include one or more central units (CUs) 210 that can communicate directly with a core network 220 via a backhaul link, or indirectly with the core network 220 through one or more disaggregated base station units (such as a Near-Real Time (Near-RT) RAN Intelligent Controller (RIC) 225 via an E2 link, or a Non-Real Time (Non-RT) RIC 215 associated with a Service Management and Orchestration (SMO) Framework 205, or both). A CU 210 may communicate with one or more distributed units (DUs) 230 via respective midhaul links, such as an F1 interface. The DUs 230 may communicate with one or more radio units (RUs) 240 via respective fronthaul links. The RUs 240 may communicate with respective UEs 104 via one or more radio frequency (RF) access links. In some implementations, the UE 104 may be simultaneously served by multiple RUs 240.

Each of the units, e.g., the CUs 210, the DUs 230, the RUs 240, as well as the Near-RT RICs 225, the Non-RT RICs 215 and the SMO Framework 205, may include one or more interfaces or be coupled to one or more interfaces configured to receive or transmit signals, data, or information (collectively, signals) via a wired or wireless transmission medium. Each of the units, or an associated processor or controller providing instructions to the communications interfaces of the units, can be configured to communicate with one or more of the other units via the transmission medium. For example, the units can include a wired interface configured to receive or transmit signals over a wired transmission medium to one or more of the other units. Additionally or alternatively, the units can include a wireless interface, which may include a receiver, a transmitter or transceiver (such as a radio frequency (RF) transceiver), configured to receive or transmit signals, or both, over a wireless transmission medium to one or more of the other units.

In some aspects, the CU 210 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 210. The CU 210 may be configured to handle user plane functionality (e.g., Central Unit-User Plane (CU-UP)), control plane functionality (e.g., Central Unit-Control Plane (CU-CP)), or a combination thereof. In some implementations, the CU 210 can be logically split into one or more CU-UP units and one or more CU-CP units. The CU-UP unit can communicate bidirectionally with the CU-CP unit via an interface, such as the E1 interface when implemented in an O-RAN configuration. The CU 210 can be implemented to communicate with the DU 230, as necessary, for network control and signaling.

The DU 230 may correspond to a logical unit that includes one or more base station functions to control the operation of one or more RUs 240. In some aspects, the DU 230 may host one or more of a radio link control (RLC) layer, a medium access control (MAC) layer, and one or more high physical (PHY) layers (such as modules for forward error correction (FEC) encoding and decoding, scrambling, modulation and demodulation, or the like) depending, at least in part, on a functional split, such as those defined by the 3rd Generation Partnership Project (3GPP). In some aspects, the DU 230 may further host one or more low PHY layers. Each layer (or module) can be implemented with an interface configured to communicate signals with other layers (and modules) hosted by the DU 230, or with the control functions hosted by the CU 210.

Lower-layer functionality can be implemented by one or more RUs 240. In some deployments, an RU 240, controlled by a DU 230, may correspond to a logical node that hosts RF processing functions, or low-PHY layer functions (such as performing fast Fourier transform (FFT), inverse FFT (iFFT), digital beamforming, physical random access channel (PRACH) extraction and filtering, or the like), or both, based at least in part on the functional split, such as a lower layer functional split. In such an architecture, the RU(s) 240 can be implemented to handle over the air (OTA) communications with one or more UEs 104. In some implementations, real-time and non-real-time aspects of control and user plane communications with the RU(s) 240 can be controlled by the corresponding DU 230. In some scenarios, this configuration can enable the DU(s) 230 and the CU 210 to be implemented in a cloud-based RAN architecture, such as a vRAN architecture.

The SMO Framework 205 may be configured to support RAN deployment and provisioning of non-virtualized and virtualized network elements. For non-virtualized network elements, the SMO Framework 205 may be configured to support the deployment of dedicated physical resources for RAN coverage requirements which may be managed via an operations and maintenance interface (such as an O1 interface). For virtualized network elements, the SMO Framework 205 may be configured to interact with a cloud computing platform (such as an open cloud (O-Cloud) 290) to perform network element life cycle management (such as to instantiate virtualized network elements) via a cloud computing platform interface (such as an O2 interface). Such virtualized network elements can include, but are not limited to, CUs 210, DUs 230, RUs 240 and Near-RT RICs 225. In some implementations, the SMO Framework 205 can communicate with a hardware aspect of a 4G RAN, such as an open eNB (O-eNB) 211, via an O1 interface. Additionally, in some implementations, the SMO Framework 205 can communicate directly with one or more RUs 240 via an O1 interface. The SMO Framework 205 also may include a Non-RT RIC 215 configured to support functionality of the SMO Framework 205.

The Non-RT RIC 215 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 225. The Non-RT RIC 215 may be coupled to or communicate with (such as via an A1 interface) the Near-RT RIC 225. The Near-RT RIC 225 may be configured to include a logical function that enables near-real-time control and optimization of RAN elements and resources via data collection and actions over an interface (such as via an E2 interface) connecting one or more CUs 210, one or more DUs 230, or both, as well as an O-eNB, with the Near-RT RIC 225.

In some implementations, to generate AI/ML models to be deployed in the Near-RT RIC 225, the Non-RT RIC 215 may receive parameters or external enrichment information from external servers. Such information may be utilized by the Near-RT RIC 225 and may be received at the SMO Framework 205 or the Non-RT RIC 215 from non-network data sources or from network functions. In some examples, the Non-RT RIC 215 or the Near-RT RIC 225 may be configured to tune RAN behavior or performance. For example, the Non-RT RIC 215 may monitor long-term trends and patterns for performance and employ AI/ML models to perform corrective actions through the SMO Framework 205 (such as reconfiguration via O1) or via creation of RAN management policies (such as A1 policies).

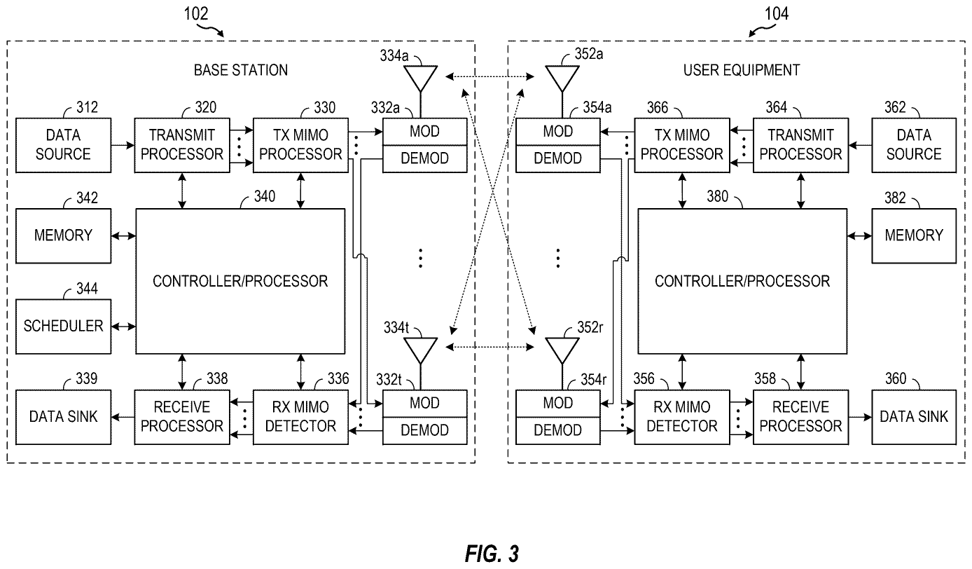

FIG. 3 depicts aspects of an example BS 102 and a UE 104.

Generally, BS 102 includes various processors (e.g., 320, 330, 338, and 340), antennas 334a-t (collectively 334), transceivers 332a-t (collectively 332), which include modulators and demodulators, and other aspects, which enable wireless transmission of data (e.g., data source 312) and wireless reception of data (e.g., data sink 339). For example, BS 102 may send and receive data between BS 102 and UE 104. BS 102 includes controller/processor 340, which may be configured to implement various functions described herein related to wireless communications.

Generally, UE 104 includes various processors (e.g., 358, 364, 366, and 380), antennas 352a-r (collectively 352), transceivers 354a-r (collectively 354), which include modulators and demodulators, and other aspects, which enable wireless transmission of data (e.g., retrieved from data source 362) and wireless reception of data (e.g., provided to data sink 360). UE 104 includes controller/processor 380, which may be configured to implement various functions described herein related to wireless communications.

In regards to an example downlink transmission, BS 102 includes a transmit processor 320 that may receive data from a data source 312 and control information from a controller/processor 340. The control information may be for the physical broadcast channel (PBCH), physical control format indicator channel (PCFICH), physical HARQ indicator channel (PHICH), physical downlink control channel (PDCCH), group common PDCCH (GC PDCCH), and/or others. The data may be for the physical downlink shared channel (PDSCH), in some examples.

Transmit processor 320 may process (e.g., encode and symbol map) the data and control information to obtain data symbols and control symbols, respectively. Transmit processor 320 may also generate reference symbols, such as for the primary synchronization signal (PSS), secondary synchronization signal (SSS), PBCH demodulation reference signal (DMRS), and channel state information reference signal (CSI-RS).

Transmit (TX) multiple-input multiple-output (MIMO) processor 330 may perform spatial processing (e.g., precoding) on the data symbols, the control symbols, and/or the reference symbols, if applicable, and may provide output symbol streams to the modulators (MODs) in transceivers 332a-332t. Each modulator in transceivers 332a-332t may process a respective output symbol stream to obtain an output sample stream. Each modulator may further process (e.g., convert to analog, amplify, filter, and upconvert) the output sample stream to obtain a downlink signal. Downlink signals from the modulators in transceivers 332a-332t may be transmitted via the antennas 334a-334t, respectively.

In order to receive the downlink transmission, UE 104 includes antennas 352a-352r that may receive the downlink signals from the BS 102 and may provide received signals to the demodulators (DEMODs) in transceivers 354a-354r, respectively. Each demodulator in transceivers 354a-354r may condition (e.g., filter, amplify, downconvert, and digitize) a respective received signal to obtain input samples. Each demodulator may further process the input samples to obtain received symbols.

MIMO detector 356 may obtain received symbols from all the demodulators in transceivers 354a-354r, perform MIMO detection on the received symbols if applicable, and provide detected symbols. Receive processor 358 may process (e.g., demodulate, deinterleave, and decode) the detected symbols, provide decoded data for the UE 104 to a data sink 360, and provide decoded control information to a controller/processor 380.

In regards to an example uplink transmission, UE 104 further includes a transmit processor 364 that may receive and process data (e.g., for the PUSCH) from a data source 362 and control information (e.g., for the physical uplink control channel (PUCCH)) from the controller/processor 380. Transmit processor 364 may also generate reference symbols for a reference signal (e.g., for the sounding reference signal (SRS)). The symbols from the transmit processor 364 may be precoded by a TX MIMO processor 366 if applicable, further processed by the modulators in transceivers 354a-354r (e.g., for SC-FDM), and transmitted to BS 102.

At BS 102, the uplink signals from UE 104 may be received by antennas 334a-t, processed by the demodulators in transceivers 332a-332t, detected by a MIMO detector 336 if applicable, and further processed by a receive processor 338 to obtain decoded data and control information sent by UE 104. Receive processor 338 may provide the decoded data to a data sink 339 and the decoded control information to the controller/processor 340.

Memories 342 and 382 may store data and program codes for BS 102 and UE 104, respectively.

Scheduler 344 may schedule UEs for data transmission on the downlink and/or uplink.

In various aspects, BS 102 may be described as transmitting and receiving various types of data associated with the methods described herein. In these contexts, “transmitting” may refer to various mechanisms of outputting data, such as outputting data from data source 312, scheduler 344, memory 342, transmit processor 320, controller/processor 340, TX MIMO processor 330, transceivers 332a-t, antenna 334a-t, and/or other aspects described herein. Similarly, “receiving” may refer to various mechanisms of obtaining data, such as obtaining data from antennas 334a-t, transceivers 332a-t, RX MIMO detector 336, controller/processor 340, receive processor 338, scheduler 344, memory 342, and/or other aspects described herein.

In various aspects, UE 104 may likewise be described as transmitting and receiving various types of data associated with the methods described herein. In these contexts, “transmitting” may refer to various mechanisms of outputting data, such as outputting data from data source 362, memory 382, transmit processor 364, controller/processor 380, TX MIMO processor 366, transceivers 354a-t, antenna 352a-t, and/or other aspects described herein. Similarly, “receiving” may refer to various mechanisms of obtaining data, such as obtaining data from antennas 352a-t, transceivers 354a-t, RX MIMO detector 356, controller/processor 380, receive processor 358, memory 382, and/or other aspects described herein.

In some aspects, one or more processors may be configured to perform various operations, such as those associated with the methods described herein, and transmit (output) to or receive (obtain) data from another interface that is configured to transmit or receive, respectively, the data.

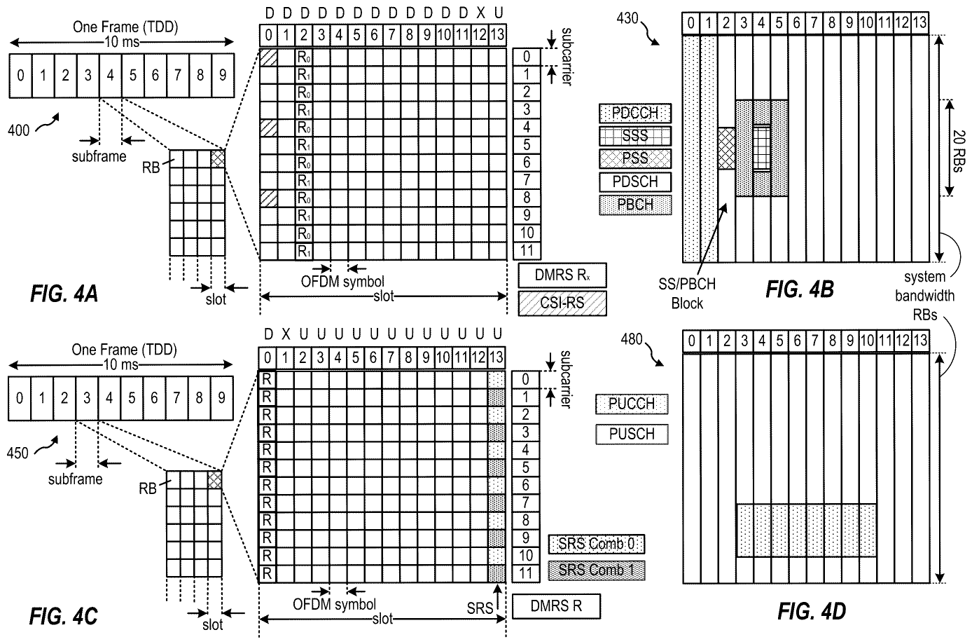

FIGS. 4A, 4B, 4C, and 4D depict aspects of data structures for a wireless communications network, such as wireless communications network 100 of FIG. 1.

In particular, FIG. 4A is a diagram 400 illustrating an example of a first subframe within a 5G (e.g., 5G NR) frame structure, FIG. 4B is a diagram 430 illustrating an example of DL channels within a 5G subframe, FIG. 4C is a diagram 450 illustrating an example of a second subframe within a 5G frame structure, and FIG. 4D is a diagram 480 illustrating an example of UL channels within a 5G subframe.

Wireless communications systems may utilize orthogonal frequency division multiplexing (OFDM) with a cyclic prefix (CP) on the uplink and downlink. Such systems may also support half-duplex operation using time division duplexing (TDD). OFDM and single-carrier frequency division multiplexing (SC-FDM) partition the system bandwidth (e.g., as depicted in FIGS. 4B and 4D) into multiple orthogonal subcarriers. Each subcarrier may be modulated with data. Modulation symbols may be sent in the frequency domain with OFDM and/or in the time domain with SC-FDM.

A wireless communications frame structure may be frequency division duplex (FDD), in which, for a particular set of subcarriers, subframes within the set of subcarriers are dedicated for either DL or UL. Wireless communications frame structures may also be time division duplex (TDD), in which, for a particular set of subcarriers, subframes within the set of subcarriers are dedicated for both DL and UL.

In FIGS. 4A and 4C, the wireless communications frame structure is TDD where D is DL, U is UL, and X is flexible for use between DL/UL. UEs may be configured with a slot format through a received slot format indicator (SFI) (dynamically through DL control information (DCI), or semi-statically/statically through radio resource control (RRC) signaling). In the depicted examples, a 10 ms frame is divided into 10 equally sized 1 ms subframes. Each subframe may include one or more time slots. In some examples, each slot may include 7 or 14 symbols, depending on the slot format. Subframes may also include mini-slots, which generally have fewer symbols than an entire slot. Other wireless communications technologies may have a different frame structure and/or different channels.

In certain aspects, the number of slots within a subframe is based on a slot configuration and a numerology. For example, for slot configuration 0, different numerologies (μ) 0 to 6 allow for 1, 2, 4, 8, 16, 32, and 64 slots, respectively, per subframe. For slot configuration 1, different numerologies 0 to 2 allow for 2, 4, and 8 slots, respectively, per subframe. Accordingly, for slot configuration 0 and numerology μ, there are 14 symbols/slot and 2μ slots/subframe. The subcarrier spacing and symbol length/duration are a function of the numerology. The subcarrier spacing may be equal to 2^{μ}×15 kHz, where μ is the numerology 0 to 6. As such, the numerology μ=0 has a subcarrier spacing of 15 kHz and the numerology μ=6 has a subcarrier spacing of 960 kHz. The symbol length/duration is inversely related to the subcarrier spacing. FIGS. 4A, 4B, 4C, and 4D provide an example of slot configuration 0 with 14 symbols per slot and numerology μ=2 with 4 slots per subframe. The slot duration is 0.25 ms, the subcarrier spacing is 60 kHz, and the symbol duration is approximately 16.67 μs.

As depicted in FIGS. 4A, 4B, 4C, and 4D, a resource grid may be used to represent the frame structure. Each time slot includes a resource block (RB) (also referred to as physical RBs (PRBs)) that extends, for example, 12 consecutive subcarriers. The resource grid is divided into multiple resource elements (REs). The number of bits carried by each RE depends on the modulation scheme.

As illustrated in FIG. 4A, some of the REs carry reference (pilot) signals (RS) for a UE (e.g., UE 104 of FIGS. 1 and 3). The RS may include demodulation RS (DMRS) and/or channel state information reference signals (CSI-RS) for channel estimation at the UE. The RS may also include beam measurement RS (BRS), beam refinement RS (BRRS), and/or phase tracking RS (PT-RS).

FIG. 4B illustrates an example of various DL channels within a subframe of a frame. The physical downlink control channel (PDCCH) carries DCI within one or more control channel elements (CCEs), each CCE including, for example, nine RE groups (REGs), each REG including, for example, four consecutive REs in an OFDM symbol.

A primary synchronization signal (PSS) may be within symbol 2 of particular subframes of a frame. The PSS is used by a UE (e.g., 104 of FIGS. 1 and 3) to determine subframe/symbol timing and a physical layer identity.

A secondary synchronization signal (SSS) may be within symbol 4 of particular subframes of a frame. The SSS is used by a UE to determine a physical layer cell identity group number and radio frame timing.

Based on the physical layer identity and the physical layer cell identity group number, the UE can determine a physical cell identifier (PCI). Based on the PCI, the UE can determine the locations of the aforementioned DMRS. The physical broadcast channel (PBCH), which carries a master information block (MIB), may be logically grouped with the PSS and SSS to form a synchronization signal (SS)/PBCH block. The MIB provides a number of RBs in the system bandwidth and a system frame number (SFN). The physical downlink shared channel (PDSCH) carries user data, broadcast system information not transmitted through the PBCH such as system information blocks (SIBs), and/or paging messages.

As illustrated in FIG. 4C, some of the REs carry DMRS (indicated as R for one particular configuration, but other DMRS configurations are possible) for channel estimation at the base station. The UE may transmit DMRS for the PUCCH and DMRS for the PUSCH. The PUSCH DMRS may be transmitted, for example, in the first one or two symbols of the PUSCH. The PUCCH DMRS may be transmitted in different configurations depending on whether short or long PUCCHs are transmitted and depending on the particular PUCCH format used. UE 104 may transmit sounding reference signals (SRS). The SRS may be transmitted, for example, in the last symbol of a subframe. The SRS may have a comb structure, and a UE may transmit SRS on one of the combs. The SRS may be used by a base station for channel quality estimation to enable frequency-dependent scheduling on the UL.

FIG. 4D illustrates an example of various UL channels within a subframe of a frame. The PUCCH may be located as indicated in one configuration. The PUCCH carries uplink control information (UCI), such as scheduling requests, a channel quality indicator (CQI), a precoding matrix indicator (PMI), a rank indicator (RI), and HARQ ACK/NACK feedback. The PUSCH carries data, and may additionally be used to carry a buffer status report (BSR), a power headroom report (PHR), and/or UCI.

### Aspects Related to System Frame Number Encoding Techniques for Soft Combining

In certain wireless communication networks, a Physical Broadcast Channel (PBCH) may be periodically broadcasted by a network entity (e.g., BS 102) to all UEs (e.g., UE 104) in a cell. The PBCH may carry important system information needed for a UE to access and connect to the wireless communication network.

A payload carried on the PBCH may include various types of information, including both dynamic or time-varying information as well as static or semi-static information. For example, in some cases, the time-varying information may include parameters system frame number (SFN), which may vary from transmission to transmission of the PBCH. The SFN may identify the current frame within a repeating radio frame cycle and may enable a UE to synchronize its internal timing with a frame structure of the wireless communication network to facilitate proper communication between the network entity and the UE.

The static or semi-static information may include parameters such as a half-frame indicator, cell barring information, cell reselection information, and other information, which may remain constant or unchanged across many consecutive transmissions. Table 1, below, illustrates the various types of information that may be included within a PBCH payload and their bit sizes for sub-6 gigahertz (GHz) and above 6 GHz communication. As noted above, the SFN and the SSB index in Table 1 may correspond to the time-varying information while the remaining parameters shown in Table 1 may correspond to the static or semi-static information.

| PBCH Payload | sub-6 | above-6 | Notes |
|---|---|---|---|
| SFN | 10 | 10 | Entire SFN |
| Half-frame | 1 | 1 | Always conveyed explicitly. For |
| indicator | | | frequencies under 3 GHz, additionally |
| | | | in DMRS scrambling |
| Cell barring | 1 | 1 | From RAN2 |
| Cell reselection | 1 | 1 | From RAN2 |
| SS config | 4 | 4 | Search space zero configuration |
| SSB index | 0 | 3 | 3 additional bits conveyed in DMRS |
| | | | scrambling. |
| Default DL | 1 | 1 | 15 or 30 kHz for sub-6 |
| numerology | | | 60 or 120 kHz for above-6 |
| Raster offset | 5 | 4 | Sync/PRB raster offset indication |
| | | | including possibility for different |
| | | | numerology |
| CORESET0 | 4 | 4 | All RMSI CORESETs associated with |
| config | | | SSBs within an SSB burst set |
| Front loaded | 1 | 1 | 2nd or 3rd OFDM symbol in the slot |
| DRMS | | | |
| Reserved | 4 | 2 | |
| Total Bits | 32 | 32 | |

As noted above, the PBCH payload carries important information that allows UEs to access the wireless communication network. However, in some scenarios, UEs at the edge of the cell may not be able to decode the PBCH payload from a single transmission due to poor link conditions. In such cases, to overcome these poor link conditions, a UE may use a technique known as soft combining whereby samples (e.g., coded bit log likelihood ratio LLR values) from a current PBCH payload transmission may be combined with coded bit LLRs from one or more previous PBCH payload transmissions. By combining these samples across transmissions, the UE may be able to improve an effective signal quality and increase the chances of correctly decoding the PBCH payload.

In some cases, soft combining may work well for transmissions containing the same information. However, while soft combining may improve the likelihood of successful decoding, it may be challenging to perform across PBCH transmissions with different payloads. For example, as noted above, since the SFN may change from one transmission to the next, the PBCH payloads of consecutive transmissions may not be the same. As a result, even though much of the information carried within the PBCH payloads remains relatively static across consecutive transmission, soft combining may not be reliably used to combine these differing PBCH payloads without advanced, power-intensive processing techniques, which may significantly impact the UE's battery life. Additionally, combining differing PBCH payloads from consecutive transmissions may increase false alarms due to the UE attempting multiple combining patterns to account for the varying SFNs, leading to unnecessary processing and potential misinterpretation of the PBCH content.

In some cases, to overcome the limitations imposed onto soft combining by the time-varying information included within PBCH payloads, a network entity may be configured to split the static/semi-static information and the time-varying information into different portions of the PBCH payload and encode these different portions using separate encoding processes. The different portions of the PBCH payload may then be multiplexed together using a particular multiplexing scheme and transmitted (e.g., broadcast) to a UE.

In some cases, since the information included within the first portion of the PBCH payload is static or semi-static and remains constant across consecutive transmissions, the UE may be able to use soft combining to combine consecutive transmissions of the first portion of the PBCH payload. As a result, the UE may be able to improve the likelihood of successful decoding of the first portion of the PCBH payload without having to use the advanced, power-intensive processing techniques, which may otherwise significantly impact the UE's battery life.

However, while these techniques may enable the UE to use soft combining to receive and decode the first portion of the PBCH payload including the static or semi-static information, the UE may still be unable to use soft combining to receive and decode the second portion of the PBCH payload including the time-varying information without using the advanced, power-intensive processing techniques. This is because the UE is generally unaware of the SFN value carried by each PBCH transmission, and therefore also unaware of the absolute timing information conveyed by the SFN. Without accurate knowledge of the content of the SFN, any attempt to soft-combine multiple transmissions of the second portion of the PBCH payload may introduce errors rather than improve decoding performance, thereby negating the benefits of combining and potentially increasing the UE's power consumption.

Further, because the UE may be unable to use soft combining to receive and decode the PBCH payload, the UE may fail to obtain critical information such as the SFN in some scenarios, such as when the UE is located on an edge of a cell. Without a valid SFN, the UE may be unable to properly synchronize with frame timing of the wireless communication network, potentially leading to missed scheduling opportunities, extended delays in accessing the wireless communication network, or repeated failures to initiate communication procedures.

Accordingly, aspects of the present disclosure provide techniques for enabling a UE to use soft combining to detect and decode an SFN included within a PBCH payload, such as the second portion of the PBCH payload described above, even when the UE may not know the contents of the SEN or the absolute timing information conveyed thereby. For example, while the UE may not know the contents of the SFN or the absolute timing information conveyed thereby, the UE may know a relative timing between two consecutive PBCH payloads carrying consecutive SFNs and may also know how much the content of the SFN increments between the two consecutive PBCH payloads, which may be used to enable soft combining.

For example, the techniques presented herein include techniques for encoding SFNs in a particular manner and applying certain modification functions to consecutive PBCH payloads carrying these encoded SFNs, including a fixed permutation and transform function, which may enable the UE to use soft combining to combine the consecutive PBCH payloads to detect and decode an SFN while only knowing the time difference or relative timing between the consecutive PBCH payloads. Accordingly, the techniques presented herein may allow the UE to reliably soft-combine multiple PBCH transmissions and accurately recover the SFN, thereby improving decoding performance, reducing power consumption, and enabling proper frame synchronization with the wireless network.

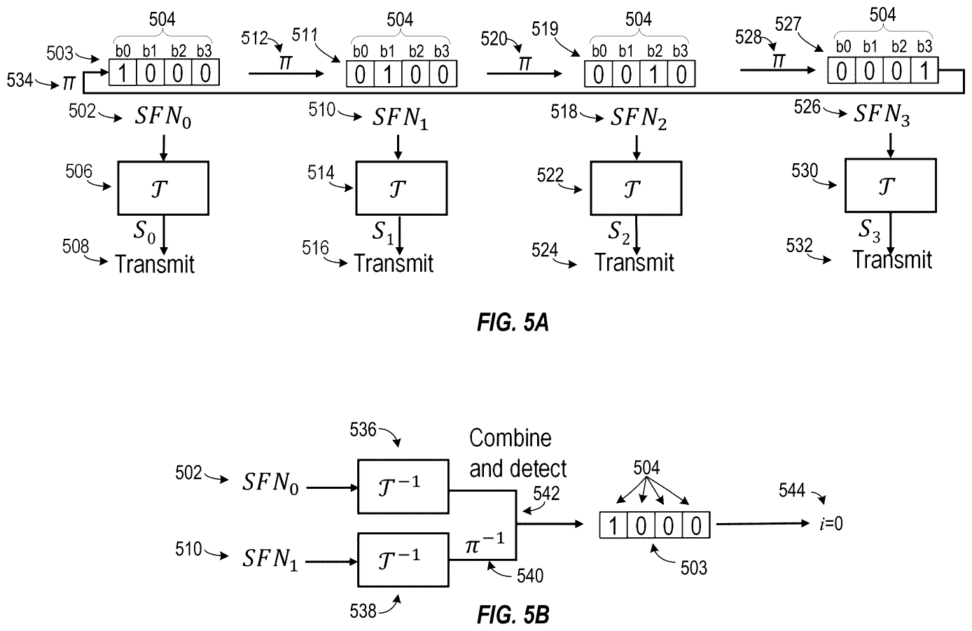

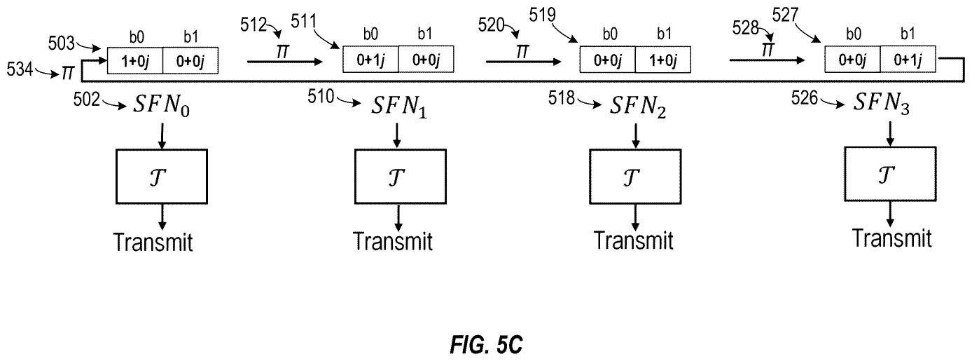

FIGS. 5A and 5B include simplified network-side and UE-side process flows, respectively, including operations illustrating the encoding techniques and modification functions that may be used to enable soft combining of PBCH payloads including time-varying information, such as SFNs. In some cases, the operations illustrated in FIG. 5A may be performed by one or more processors of a network entity, such as the BS 102 depicted and described with respect to FIGS. 1 and 3 or a disaggregated base station depicted and described with respect to FIG. 2. In some cases, the operations illustrated in FIG. 5B may be performed by one or more processors of a UE, such as the UE 104 depicted and described with respect to FIGS. 1 and 3.

As shown in FIG. 5A, a network entity may obtain a first PBCH payload 502 (e.g., SFN₀, where 0 corresponds to time index i=0) including a first encoded SFN 503 that indicates a first SFN of a set of SFNs. In some cases, to obtain the first PBCH payload 502 including the first encoded SFN 503, the network entity may encode the first SFN using a particular encoding scheme. In some cases, the first encoded SFN 503 may be pre-encoded and stored within memory (e.g., memory 342 illustrated in FIG. 3) of the network entity and, in order to obtain the first PBCH payload 502 including the first encoded SFN 503, the network entity may obtain the first encoded SFN 503 from the memory. In some cases, the network entity may obtain the first PBCH payload 502 including the first encoded SFN 503 based on a fixed permutation x applied to another PBCH payload including another encoded SFN transmitted immediately prior to the first encoded SFN 503, such as a fourth PBCH payload 526 including a fourth encoded SFN 527, as will be described in more detail below.

In some cases, the first encoded SFN 503 may include k bits, which may be used to indicate the first SFN of the set of SFNs by means of the encoding scheme. In some cases, as shown in FIG. 5A, the encoding scheme used to encode the first SFN to obtain the first encoded SFN 503 may encode the first SFN as a one-hot vector. In other words, the first encoded SFN 503 may comprise a one-hot vector that indicates the first SFN of the set of SFNs. In some cases, the one-hot vector may have a length K=2^{k}. As shown in the example of FIG. 5A, k may equal 2, resulting in the one-hot vector having a length equal to 4 (e.g., 2²).

Further, as shown, the one-hot vector of the first encoded SFN includes a plurality of different bit-positions 504 and each bit-position of the plurality of different bit-positions 504 corresponds to a different time index t and a different SFN of the set of SFNs. Since k is equal to 2 in FIG. 5A, the plurality of different bit-positions 504 includes 4 bit-positions (e.g., the one-hot vector has a length equal to 4). In some cases, from left to right, the first bit-position (e.g., b0) of the first encoded SFN 503 may correspond to time index i=0 and the first SFN, the second bit-position (e.g., b1) may correspond to time index i=1 and a second SFN, the third bit-position (e.g., b2) may correspond to time index i=2 and a third SFN, and the fourth bit-position (e.g., b3) may correspond to time index i=3 and a fourth SFN.

In some cases, to indicate the first SFN, the one-hot vector of the first encoded SFN 503 may include a bit having a bit-value of one (e.g., 1) within a bit-position, of the plurality of different bit-positions 504, corresponding to the first SFN. The one-hot vector may also have bits having bit-values of zero (e.g., 0) within bit-positions, of the plurality of different bit-positions, that do not correspond to the first SFN. For example, as shown in FIG. 5A, to indicate the first SFN, the one-hot vector of the first encoded SFN 503 comprises the vector 1000, which includes a bit having the bit-value of one within the first bit-position corresponding to time index i=0 and the first SFN, and includes bits having the bit-values of zero within the second, third, and fourth bit-positions corresponding to the second SFN, third SFN, and fourth SFN, respectively.

The example shown in FIG. 5A illustrates a one-hot vector including real values. However, in some cases, the first encoded SFN may comprise a one-hot complex vector that indicates the first SFN of a set of SFNs. In some cases, when a one-hot complex vector is used, the one-hot complex vector may have a length K=2^{k-1}. Further, similar to the example shown in FIG. 5A, the one-hot complex vector may include a plurality of different bit-positions and each bit-position of the plurality of different bit-positions corresponds to a different SFN of the set of SFNs. Additionally, to indicate the first SFN, the one-hot complex vector may include a bit having a non-zero bit-value (e.g., 1 or j) within a bit-position, of the plurality of different bit-positions, corresponding to the first SFN. Additionally, the one-hot complex vector may include bits having bit-values of zero within bit-positions, of the plurality of different bit-positions, that do not correspond to the first SFN.

Additionally, rather than using one-hot vectors to indicate the SFNs of the set of SFNs, different orthogonal sequences may be used. For example, in some cases, the first encoded SFN may include a first orthogonal sequence, of a plurality of orthogonal sequences, that indicates the first SFN of a set of SFNs. In some cases, each orthogonal sequence of the plurality of orthogonal sequences may have a length K=2^{k} and may correspond to a different SFN of the set of SFNs. For example, as noted, the first orthogonal sequence may indicate the first SFN, a second orthogonal sequence may indicate the second SFN of the set of SFNs, a third orthogonal sequence may indicate the third SFN of the set of SFNs, and so on. In some cases, the plurality of orthogonal sequences, including at least the first orthogonal sequence that indicates the first SFN, may be one of a binary phase shift keying (BPSK) sequence or a quadrature phase shift keying (QPSK) sequence. In some cases, the plurality of orthogonal sequences may be generated using a compute search algorithm or a pseudo-random sequence (e.g., an m-sequence, a Gold-sequence, a ZC sequence, etc.).

After obtaining the first PBCH payload 502 (e.g., SFN₀), the network entity may then proceed with transmitting the first PBCH payload including the first encoded SFN 503 to a UE. However, in some cases, it may be inefficient to directly transmit the first PBCH payload 502. For example, if the first encoded SFN 503 of the first PBCH payload 502 (e.g., SFN₀) is encoded as a one-hot vector (e.g., that includes a bit-value of 1 in only one bit-position to indicate the corresponding first SFN), directly transmitting the first PBCH payload 502 including the one-hot vector of the first encoded SFN 503 may concentrate energy in one resource element (RE), causing the first PBCH payload 502 (e.g., SFN₀) to be susceptible to frequency-selective fading and resulting in reduced detection reliability at the UE and inefficient use of an available spectrum.

In some cases, to reduce susceptibility to frequency-selective fading and improve detection reliability and the use of available spectrum, rather than transmitting the first PBCH payload 502 directly, the network entity may first apply, at 506, a transform function J to the first PBCH payload, including the first encoded SFN 503, to convert to the first PBCH payload 502 from an SFN domain to a transform domain for transmission, resulting in a first transform-domain signal S₀ corresponding to or representing the first PBCH payload 502 in the transform domain. For example, more generally, the network entity may convert an a PBCH payload from the SFN domain to the transform domain such that Sᵢ= [symbol] (SFNᵢ) and SFNᵢ= [symbol] (Sᵢ), where SFNᵢ is the PBCH payload including an encoded SFN, Sᵢ is the PBCH payload in the transform domain, [symbol] is the transform function, and [symbol] is an inverse of the transform function J.

In some embodiments, the transform function may comprise an inverse discrete Fourier transform (IDFT) function while the inverse of the transform function may comprise a discrete Fourier transform (DFT) function. In some embodiments, the transform function may comprise an inverse fast Fourier transform (IFFT) function while the inverse of the transform function may comprise a fast Fourier transform (FFT) function. In some cases, the transform function and the inverse of the transform function may comprise a Hadamard transform (HT). In some cases, the transform function and the inverse of the transform function may comprise a fast Hadamard transform (FHT). In some cases, the transform function may comprise an identity function.

Thereafter, at 508, the network entity may transmit the first PBCH payload 502 to the UE over 2^{k} REs in a wireless channel after applying the transform function to the first PBCH payload 502. In other words, at 508, the network entity may transmit the first transform-domain signal S₀ corresponding or representing the first PBCH payload 502.

The network entity may then obtain a second PBCH payload 510 (e.g., SFN₁, where 1 corresponds to time index i=1) including a second encoded SFN 511 that indicates a second SFN of the set of SFNs. In some cases, the network entity may obtain the second PBCH payload 510 by applying a fixed permutation 512 to the first PBCH payload 502, as shown at 512. In some embodiments, the fixed permutation may comprise a cyclic shift. For example, as shown in FIG. 5A, the first encoded SFN 503 and the second encoded SFN 511 may each include a one-hot vector. Accordingly, when applying the fixed permutation to the first PBCH payload 502 including the first encoded SFN 503, the fixed permutation may cause the bit having the bit-value of one to shift bit-positions within the plurality of different bit-positions 504 of the one-hot vector of the second encoded SFN 511. For example, as can be seen, the bit having the bit-value of one within the one-hot vector of the second encoded SFN 511 may be shifted from the first bit-position (e.g., as it appears in the first encoded SFN 503) to the second bit-position within the plurality of different bit-positions 504 of the second encoded SFN 511.

In some cases, the fixed permutation may comprise a fixed length-2^{k} permutation having a period of 2^{k}. For example, in some cases, when applying the fixed length-2^{k} permutation to a PBCH payload including an encoded SFN, the encoded SFN may be permuted back to itself only after applying the same permutation K=2^{k} times. For example, for k=3, the fixed permutation may be π(12345678)=(5 4 7 6 2 8 1 3). In some cases, the fixed permutation may comprise a permutation having a period smaller than 2^{k} (e.g., smaller than the length 2^{k} of the first encoded SFN 503), which may enable coding gain associated with repetition.

In some cases, the fixed permutation may enable the UE to use soft combining with PBCH payloads including time-varying information (e.g., SFN), such as the first PBCH payload 502 and the second PBCH payload 510. For example, in some cases, the fixed permutation may be known to the UE ahead of time (e.g., pre-programmed by a manufacturer of the UE or signaled to the UE by the network entity). Additionally, the UE may know the relative timing between two consecutive PBCH payloads, such as the first PBCH payload 502 and the second PBCH payload 510, and may also know how much the content of the PBCH payloads (e.g., the encoded SFNs) increment between the two consecutive PBCH payloads based on the fixed permutation. For example, in some cases, the fixed permutation may be defined such that SFNᵢ₊₁=π(SFNᵢ) and SFNᵢ=π⁻¹(SFNᵢ₊₁), where SFNᵢ and SFNᵢ₊₁ are two consecutive PBCH payloads with SFNᵢ occurring earlier in time, x is the fixed permutation, and π⁻¹ is an inverse of the fixed permutation.

As a result, even though the content of the first PBCH payload 502 and the second PBCH payload 510 (e.g., the first encoded SFN 503 and the second encoded SFN 511, respectively) may vary between transmissions, the UE may still be able to use a soft combining procedure to improve detection of, for example, the first encoded SFN 503 included in the first PBCH payload 502. For example, in some cases, the UE may apply an inverse of the known fixed permutation (e.g., π⁻¹) to the second PBCH payload 510 to “reconstruct” the first PBCH payload 502 (including the first encoded SFN 503) and may then combine the “reconstructed” first PBCH payload 502 with the first PBCH payload 502 that is received over 2^{k} REs in the wireless channel to improve detection reliability of the first encoded SFN 503. Additional details regarding the operations performed by the UE associated with soft combining are described below with respect to FIG. 5B.

After obtaining the second PBCH payload 510 (e.g., SFN₁), the network entity may then apply the transform function to the second PBCH payload 510 at 514 to convert to the second PBCH payload 510 from the SFN domain to the transform domain for transmission, resulting in a second transform-domain signal Sᵢ corresponding to or representing the second PBCH payload 510 in the transform domain. Thereafter, at 516, the network entity may transmit the second PBCH payload 510 to the UE over 2^{k} REs in the wireless channel after applying the transform function [symbol] to the second PBCH payload 510. In other words, at 516, the network entity may transmit the second transform-domain signal S₁ corresponding or representing the second PBCH payload 510.

Thereafter, the network entity may obtain a third PBCH payload 518 (e.g., SFN₂, where 2 corresponds to time index i=2), including a third encoded SFN 519, by applying the fixed permutation to the second PBCH payload 510, as shown at 520. As shown, the third encoded SFN 519 may comprise a one-hot vector and, as a result of applying the fixed permutation to the second PBCH payload 510, the bit having the bit-value of one within the one-hot vector of the third encoded SFN 519 may be shifted from the second bit-position (e.g., as it appears in the second encoded SFN 511) to the third bit-position within the plurality of different bit-positions 504 of the third encoded SFN 519.

After obtaining the third PBCH payload 518 (e.g., SFN₂), the network entity may then apply the transform function to the third PBCH payload 518 at 522 to convert to the third PBCH payload 518 from the SFN domain to the transform domain for transmission, resulting in a third transform-domain signal S₂ corresponding to or representing the third PBCH payload 518 in the transform domain. Thereafter, at 524, the network entity may transmit the third PBCH payload 518 to the UE over 2^{k} REs in the wireless channel after applying the transform function [symbol] to the third PBCH payload 518. In other words, at 524, the network entity may transmit the third transform-domain signal S₂ corresponding or representing the third PBCH payload 518.

Thereafter, the network entity may obtain the fourth PBCH payload 526 (e.g., SFN₃, where 3 corresponds to time index i=3), including the fourth encoded SFN 527, by applying the fixed permutation to the third PBCH payload 518, as shown at 528. As shown, the fourth encoded SFN 527 may comprise a one-hot vector and, as a result of applying the fixed permutation to the third PBCH payload 518, the bit having the bit-value of one within the one-hot vector of the fourth encoded SFN 527 may be shifted from the third bit-position (e.g., as it appears in the third encoded SFN 519) to the fourth bit-position within the plurality of different bit-positions 504 of the fourth encoded SFN 527.

After obtaining the fourth PBCH payload 526 (e.g., SFN₃), the network entity may then apply the transform function to the fourth PBCH payload 526 at 530 to convert to the fourth PBCH payload 526 from the SFN domain to the transform domain for transmission, resulting in a fourth transform-domain signal S₃ corresponding to or representing the fourth PBCH payload 526 in the transform domain. Thereafter, at 532, the network entity may transmit the fourth PBCH payload 526 to the UE over 2^{k} REs in the wireless channel after applying the transform function [symbol] to the fourth PBCH payload 526. In other words, at 532, the network entity may transmit the fourth transform-domain signal S₃ corresponding or representing the fourth PBCH payload 526.

Thereafter, since k may equal 2 in FIG. 5A, resulting in the encoded SFNs (e.g., the first encoded SFN 503, the second encoded SFN 511, the third encoded SFN 519, and the fourth encoded SFN 527) having a length equal to 4 (e.g., 22), when applying the fixed permutation to the fourth PBCH payload 526 at 534, the fourth encoded SFN 527 included in the fourth PBCH payload 526 may be permuted back to the first encoded SFN 503 included in the first PBCH payload 502. As a result, the operations illustrated within FIG. 5A and described above may repeat themselves starting at 502 with the network entity again obtaining the first PBCH payload 502 including the first encoded SFN 503.

As noted above, FIG. 5B illustrates a simplified UE-side process flow, including operations that may be performed by the UE for soft combining of PBCH payloads including time-varying information, such as SFNs.

As shown, the UE may receive, over the wireless channel, the first PBCH payload 502 including the first encoded SFN that indicates the first SFN of the set of SFNs. Additionally, as shown, the UE may receive, over the wireless channel, the second PBCH payload 510 including the second encoded SFN that indicates the second SFN of the set of SFNs. For the sake of simplicity, the UE is illustrated in FIG. 5B and described herein as directly receiving the first PBCH payload 502 and second PBCH payload 510. However, it should be appreciated that, at the time of reception, the UE may not know which specific PBCH payloads it has received and may perform further processing, such as soft combining and detection, as described below, to determine which PBCH payload(s) and encoded SFN it has received.

As discussed above, the first PBCH payload 502 may be based on the fixed permutation π and the transform function [symbol] . For example, as discussed with respect to FIG. 5A, in some cases, the first PBCH payload 502 including the first encoded SFN 503 may be obtained by applying the fixed permutation to the fourth PBCH payload 526 including the fourth encoded SFN 527. Thereafter, the transformation function may be applied to the first PBCH payload 502 to convert the first PBCH payload 502 from the SFN domain to the transform domain prior to transmission to the UE.

Additionally, as discussed above, the second PBCH payload 510 may be based on the first PBCH payload 502 including the first encoded SFN, the fixed permutation π, and the transform function [symbol] . For example, as discussed with respect to FIG. 5A, in some cases, the second PBCH payload 510 including the second encoded SFN 511 may be obtained by applying the fixed permutation to the first PBCH payload 502 including the first encoded SFN 503. Thereafter, the transformation function may be applied to the second PBCH payload 510 to convert the second PBCH payload 510 from the SFN domain to the transform domain prior to transmission to the UE.

As noted above, the UE may be configured to use soft combining with PBCH payloads including time-varying information (e.g., SFNs), such as the first PBCH payload 502 and the second PBCH payload 510. However, because the contents of the first PBCH payload 502 and the second PBCH payload 510 received by the UE are different (e.g., the first encoded SFN 503 included in the first PBCH payload 502 is different from the second encoded SFN 511 included in the second PBCH payload 510), the UE would normally be unable to use soft combining the first PBCH payload 502 and the second PBCH payload 510. However, because the first PBCH payload 502 and the second PBCH payload 510 are received consecutively and because the UE may know how much the second encoded SFN 511 of the second PBCH payload 510 increments or changes relative to the first encoded SFN 503 of the first PBCH payload 502 based on the fixed permutation, the UE may be able to “re-construct” one of the first PBCH payload 502 or the second PBCH payload 510 from the other, allowing the UE to use soft combining to detect one of the first encoded SFN 503 or the second encoded SFN 511.

For example, after receiving the first PBCH payload 502 and the second PBCH payload 510, the UE may then apply an inverse of the transform function (e.g., [symbol] ) to the first PBCH payload 502, as shown at 536, and may also apply the inverse of the transform function (e.g., [symbol] ) to the second PBCH payload 510, as shown at 538. In some cases, applying the inverse of the transform function to the first PBCH payload 502 and to the second PBCH payload 510 may convert the first PBCH payload 502 and the second PBCH payload 510 back to the SFN domain from the transform domain.

As shown at 540, after applying the inverse of the transform function to the second PBCH payload 510 received over the wireless channel, the UE may then apply an inverse of the fixed permutation (e.g., π⁻¹) to the second PBCH payload 510 to obtain or “re-construct” the first PBCH payload 502 including the first encoded SFN. As a result, the “re-constructed” first PBCH payload 502 obtained by applying the inverse of the fixed permutation (e.g., π⁻¹) to the second PBCH payload 510 may now include the same content (e.g., the first encoded SFN 503), enabling the UE to use soft combining.

For example, in some cases, the UE may perform a soft combining procedure to detect the first encoded SFN 503 based on the first PBCH payload and the second PBCH payload. Specifically, for example, as shown at 542 in FIG. 5, the UE may combine the first PBCH payload 502 received over the wireless channel with the “re-constructed” first PBCH payload 502 obtained based on applying the inverse of the fixed permutation to the second PBCH payload 510. Thereafter, the UE may detect the first encoded SFN 503 based on the combination of the first PBCH payloads 502. In some cases, detection of the first encoded SFN 503 may be improved since the soft combining allows the UE to exploit partial information or signal energy from each first PBCH payload 502, effectively boosting the overall signal-to-noise ratio (SNR).

After detecting the first encoded SFN 503, the UE may then decode the detected first encoded SFN 503 to determine the first SFN, of the set of SFNs, indicated by the first encoded SFN 503. For example, in some cases, because the first encoded SFN 503 is encoded as a one-hot vector, the UE may be configured to determine the bit-position, of the plurality of bit-positions 504, within the one-hot vector including a bit having a bit-value of 1. As shown, the UE may determine that the bit having the bit-value of one is included within the first bit-position, corresponding to time index i=0, within the one-hot vector. Accordingly, based on the determined bit-position within the one-hot vector of the first encoded SFN 503, the UE may determine the time index i=0, as shown at 544, and that this time index corresponds to the first SFN.

It should be appreciated that, while FIG. 5B illustrates the UE applying the inverse of the fixed permutation to the second PBCH payload 510 to obtain or “re-construct” the first PBCH payload 502 in order to perform soft combining, in other cases, the UE may also be configured to apply the fixed permutation to the first PBCH payload 502 to obtain or “re-construct” the second PBCH payload 510 including the second encoded SFN 511. The UE may then be configured to combine the second PBCH payload 510 received over the wireless channel with the “re-constructed” second PBCH payload 510 obtained based on applying the fixed permutation to the first PBCH payload 502. Thereafter, the UE may detect the second encoded SFN 511 based on the combination of the second PBCH payloads 510. After detecting the second encoded SFN 511, the UE may then decode the detected second encoded SFN 511 to determine the second SFN, of the set of SFNs, indicated by the second encoded SFN 511.

Additionally, it should be appreciated that, while FIG. 5B only illustrates the UE receiving two PBCH payloads and performing soft combining based on these two PBCH payloads, the techniques described above may enable the UE may receive any number of PBCH payloads and perform the soft combining based on these PBCH payloads, simply by applying the fixed permutation or the inverse of the fixed permutation a corresponding number of additional times. For example, if the UE were to also receive the third PBCH payload 518 (e.g., in addition to the first PBCH payload 502 and the second PBCH payload 510), the UE may be able to obtain or “re-construct” the first PBCH payload 502 by first applying the inverse of the transform function to the third PBCH payload 518 and then applying the inverse of the fixed permutation twice to the third PBCH payload 518. In other cases, the UE may be able to obtain or “re-construct” the third PBCH payload 518 by first applying the inverse of the transform function to the first PBCH payload 502 and the second PBCH payload 510, and then applying the fixed permutation twice to the first PBCH payload 502 received over the wireless channel and once to the second PBCH payload 510 received over the wireless channel.

Additionally, in some cases, the UE may be able to use a combination of the applying the fixed permutation and the inverse of the fixed permutation to obtain or “re-construct” a particular PBCH payload. For example, assuming the UE receives the first PBCH payload 502, the second PBCH payload 510, and the third PBCH payload 518. In some cases, the UE may be able to obtain or “re-construct” the second PBCH payload 510 (e.g., for performing the soft combining procedure) by first applying the inverse of the transform function to the first PBCH payload 502 and to the third PBCH payload 518, and then applying the fixed permutation to the first PBCH payload 502 received over the wireless channel and applying the inverse of the fixed permutation to the third PBCH payload 518 received over the wireless channel. The UE may then be able to combine the second PBCH payload 510 received over the wireless channel with the two “re-constructed” second PBCH payloads 510 obtained by applying the fixed permutation to the first PBCH payload 502 and by applying the inverse of the fixed permutation to the third PBCH payload 518.

FIG. 5C illustrates a simplified network-side process flow including operations for enabling soft combining of PBCH payloads when SFN is encoded as a one-hot complex vector. As illustrated in FIG. 5C, assuming a 2-bit SFN, rather than using a real vector having a length of 22 (e.g., including 4 bit-positions) where the fixed permutation shifts the bit-position of the bit having the bit-value of one across four different bit-positions, as shown in FIG. 5A, when using a one-hot complex vector, the one-hot complex vector may have a length of 22-1 (e.g., including 2 bit-positions, b0 and b1) and the fixed permutation may alternate between real and imaginary bit-values within each bit-position (e.g., b0 and b1).

For example, as shown in FIG. 5C, the one-hot complex vector of the first encoded SFN 503 included within the first PBCH payload 502 may have a real bit-value of one within a first bit-position (e.g., b1) and a bit-value of zero within a second bit-position (e.g., b2). Thereafter, to obtain the second PBCH payload 510 including the second encoded SFN 511, the fixed permutation 512 applied by the network entity to the first PBCH payload 502 may cause the bit-value within the first bit-position of the one-hot complex vector to shift or flip to an imaginary bit-value j.

Similarly, to obtain the third PBCH payload 518 including the third encoded SFN 519, the fixed permutation 520 applied by the network entity to the second PBCH payload 510 may cause the bit-value within the second bit-position of the one-hot complex vector to shift or flip to a real bit-value of one while the bit-value within the first bit-position may flip to a bit-value of zero.

Thereafter, to obtain the fourth PBCH payload 526 including the fourth encoded SFN 527, the fixed permutation 528 applied by the network entity to the third PBCH payload 518 may cause the bit-value within the second bit-position of the one-hot complex vector to shift or flip to an imaginary bit-value of j.

The first PBCH payload 502 including the first encoded SFN 503 may then be obtained again by applying the fixed permutation 534 to the fourth PBCH payload 526, which may cause the bit-value within the first bit-position to shift or flip to a real bit-value of one while the bit-value within the second bit-position may flip to a bit-value of zero.

As illustrated, the remaining operations illustrated within FIG. 5C remain largely the same as described with respect to FIG. 5A with the network entity applying the transform function [symbol] to the first PBCH payload 502, the second PBCH payload 510, the third PBCH payload 518, and the fourth PBCH payload 526 prior to each of these PBCH payloads being transmitted to the UE. The UE may then use the techniques described with respect to FIG. 5B to perform soft combining on the PBCH payloads, received from the network entity, that include SFNs encoded as a one-hot complex vectors.

It should be appreciated that, due to a current SFN configuration within 5G new radio (NR), the preceding discussion focuses on a scenario in which a length of the encoded SFNs is K=2^{k}. For example, in NR, the SFN may reset every 1024 frames where each frame is 10 milliseconds. Accordingly, if the SFN is transmitted once per 20 ms, k=9 bits are time-varying, and the transmission period may be 2⁹. However, the same techniques described above may also be used with transmission periods other than 2^{k} or when a length K of an encoded SFN is not equal to 2^{k}. For example, in some cases, the same techniques described above may also be used for SFN that resets after K instances. In this scenario, a Hadamard transform may be avoided. Additionally, since DFT/IDFT complexity may be high. Restricting K may lead to a fast DFT implementation. For example, similar to the limitation for DFT-s, K may be limited to have the structure of 2^{a}3^{b}5^{c}. More generally K may be limited to the form of a product of powers of a few small prime numbers.

### Example Operations

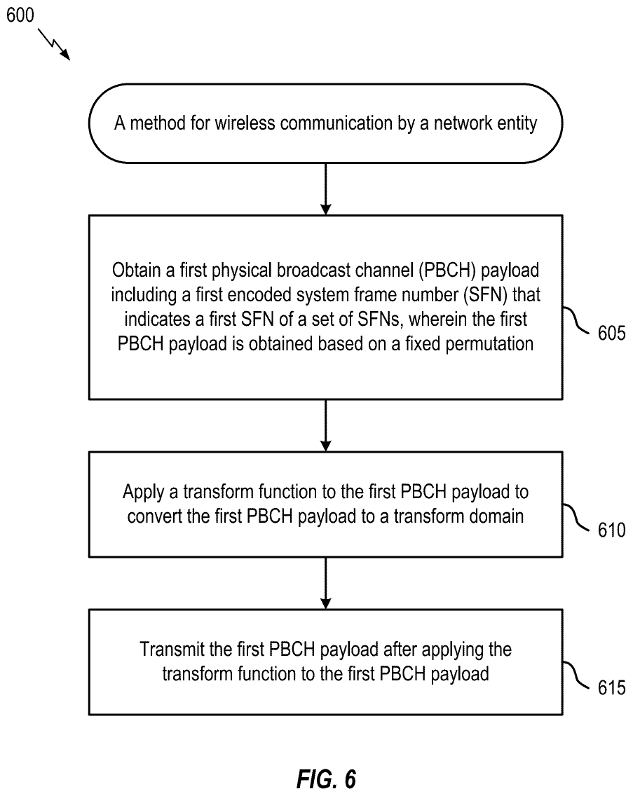

FIG. 6 shows an example of a method 600 of wireless communication by a network entity, such as a BS 102 of FIGS. 1 and 3, or a disaggregated base station as discussed with respect to FIG. 2.

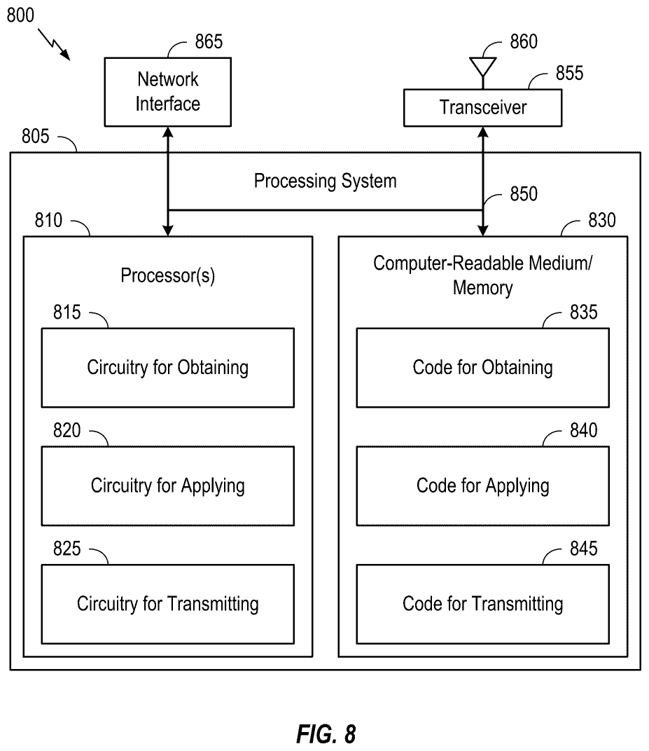

Method 600 begins at step 605 with obtaining a first physical broadcast channel (PBCH) payload including a first encoded system frame number (SFN) that indicates a first SFN of a set of SFNs, wherein the first PBCH payload is obtained based on a fixed permutation. In some cases, the operations of this step refer to, or may be performed by, circuitry for obtaining and/or code for obtaining as described with reference to FIG. 8.

Method 600 then proceeds to step 610 with applying a transform function to the first PBCH payload to convert the first PBCH payload to a transform domain. In some cases, the operations of this step refer to, or may be performed by, circuitry for applying and/or code for applying as described with reference to FIG. 8.

Method 600 then proceeds to step 615 with transmitting the first PBCH payload after applying the transform function to the first PBCH payload. In some cases, the operations of this step refer to, or may be performed by, circuitry for transmitting and/or code for transmitting as described with reference to FIG. 8.

In some aspects, the method 600 further includes applying the fixed permutation to the first PBCH payload to obtain a second PBCH payload including a second encoded SFN that indicates a second SFN of the set of SFNs. In some cases, the operations of this step refer to, or may be performed by, circuitry for applying and/or code for applying as described with reference to FIG. 8.

In some aspects, the method 600 further includes applying the transform function to the second PBCH payload to convert the second PBCH payload to a transform domain. In some cases, the operations of this step refer to, or may be performed by, circuitry for applying and/or code for applying as described with reference to FIG. 8.

In some aspects, the method 600 further includes transmitting the second PBCH payload after applying the transform function to the second PBCH payload, wherein the first SFN indicated by the first encoded SFN and the second SFN indicated by the second encoded SFN are consecutive SFNs. In some cases, the operations of this step refer to, or may be performed by, circuitry for transmitting and/or code for transmitting as described with reference to FIG. 8.

In some aspects, obtaining the first PBCH payload including the first encoded SFN comprises applying the fixed permutation to a second PBCH payload including a second encoded SFN, transmitted before the first PBCH payload, to obtain the first PBCH payload including the first encoded SFN.

In some aspects, the first encoded SFN comprises k bits.

In some aspects, the first encoded SFN comprises a one-hot vector that indicates the first SFN of the set of SFNs, wherein the one-hot vector includes a plurality of different bit-positions; each bit-position of the plurality of different bit-positions corresponds to a different SFN of the set of SFNs; and to indicate the first SFN: the one-hot vector includes a bit having a bit-value of one within a bit-position, of the plurality of different bit-positions, corresponding to the first SFN; and the one-hot vector includes bits having bit-values of zero within bit-positions, of the plurality of different bit-positions, that do not correspond to the first SFN.

In some aspects, the one-hot vector has a length K that is equal to 2^{k}.

In some aspects, the one-hot vector has a length K that is not equal to 2^{k}.

In some aspects, the first encoded SFN comprises a one-hot complex vector that indicates the first SFN of a set of SFNs, wherein: the one-hot complex vector includes a plurality of different bit-positions; each bit-position of the plurality of different bit-positions corresponds to a different SFN of the set of SFNs; and to indicate the first SFN: the one-hot complex vector includes a bit having a non-zero bit-value within a bit-position, of the plurality of different bit-positions, corresponding to the first SFN; and the one-hot complex vector includes bits having bit-values of zero within bit-positions, of the plurality of different bit-positions, that do not correspond to the first SFN.

In some aspects, the one-hot complex vector has a length K that is equal to 2^{k-1}.

In some aspects, the one-hot complex vector has a length K that is not equal to 2^{k-1}.

In some aspects, the first encoded SFN comprises a particular orthogonal sequence, of a plurality of orthogonal sequences, that indicates the first SFN of a set of SFNs, wherein each orthogonal sequence of the plurality of orthogonal sequences corresponds to a different SFN of the set of SFNs.

In some aspects, each orthogonal sequence of the plurality of orthogonal sequences has a length K that is equal to 2^{k}.

In some aspects, each orthogonal sequence of the plurality of orthogonal sequences has a length K that is not equal to 2^{k}.

In some aspects, the particular orthogonal sequence comprises one of a binary phase shift keying (BPSK) sequence or a quadrature phase shift keying (QPSK) sequence. In some aspects, the transform function comprises an identity function.

In some aspects, the fixed permutation comprises one of: a cyclic shift; a fixed length-2^{k} permutation having a period of 2^{k}; or a permutation having a period smaller than 2^{k}.

In some aspects, the transform function comprises one of: an inverse discrete Fourier transform (IDFT) function; an inverse fast Fourier transform (IFFT) function; a Hadamard transform (HT); or a fast Hadamard transform (FHT).

In one aspect, method 600, or any aspect related to it, may be performed by an apparatus, such as communications device 800 of FIG. 8, which includes various components operable, configured, or adapted to perform the method 600. Communications device 800 is described below in further detail.

Note that FIG. 6 is just one example of a method, and other methods including fewer, additional, or alternative steps are possible consistent with this disclosure.

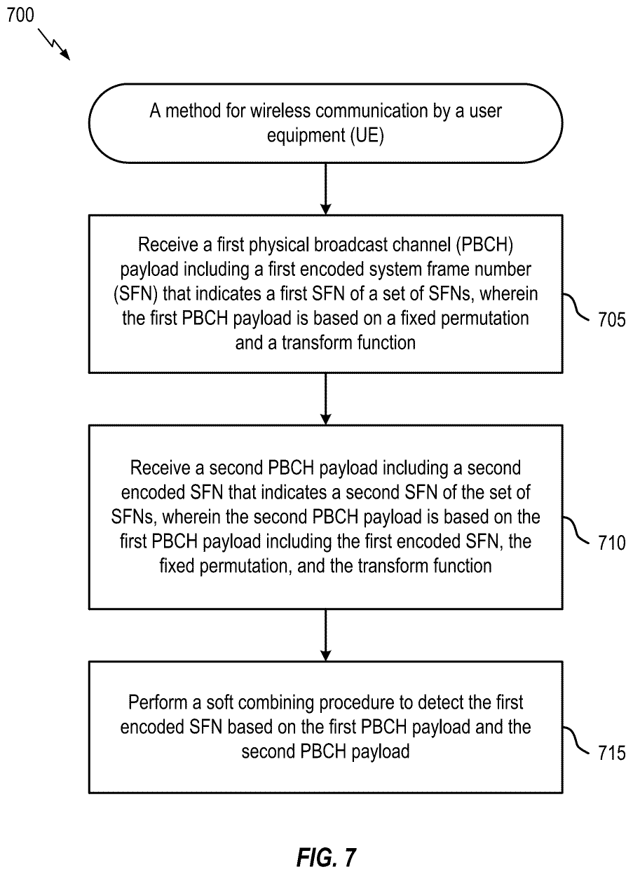

FIG. 7 shows an example of a method 700 of wireless communication by a user equipment (UE), such as a UE 104 of FIGS. 1 and 3.

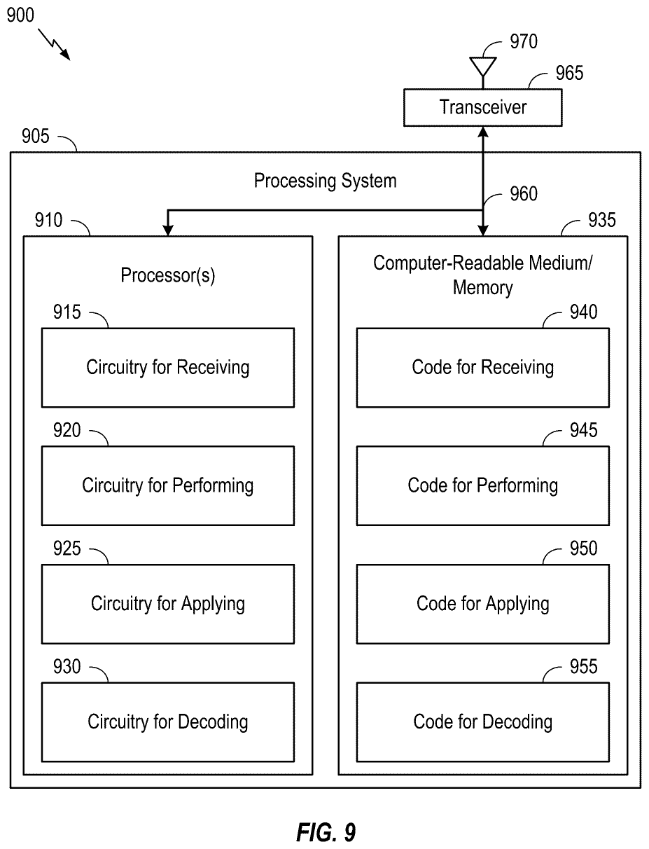

Method 700 begins at step 705 with receiving a first physical broadcast channel (PBCH) payload including a first encoded system frame number (SFN) that indicates a first SFN of a set of SFNs, wherein the first PBCH payload is based on a fixed permutation and a transform function. In some cases, the operations of this step refer to, or may be performed by, circuitry for receiving and/or code for receiving as described with reference to FIG. 9.

Method 700 then proceeds to step 710 with receiving a second PBCH payload including a second encoded SFN that indicates a second SFN of the set of SFNs, wherein the second PBCH payload is based on the first PBCH payload including the first encoded SFN, the fixed permutation, and the transform function. In some cases, the operations of this step refer to, or may be performed by, circuitry for receiving and/or code for receiving as described with reference to FIG. 9.

Method 700 then proceeds to step 715 with performing a soft combining procedure to detect the first encoded SFN based on the first PBCH payload and the second PBCH payload. In some cases, the operations of this step refer to, or may be performed by, circuitry for performing and/or code for performing as described with reference to FIG. 9.

In some aspects, the method 700 further includes applying an inverse of the transform function to the first PBCH payload. In some cases, the operations of this step refer to, or may be performed by, circuitry for applying and/or code for applying as described with reference to FIG. 9.

In some aspects, the method 700 further includes applying the inverse of the transform function to the second PBCH payload. In some cases, the operations of this step refer to, or may be performed by, circuitry for applying and/or code for applying as described with reference to FIG. 9.

In some aspects, the method 700 further includes applying, after applying the inverse of the transform function to the second PBCH payload, an inverse of the fixed permutation to the second PBCH payload to obtain the first PBCH payload. In some cases, the operations of this step refer to, or may be performed by, circuitry for applying and/or code for applying as described with reference to FIG. 9.

In some aspects, performing the soft combining procedure comprises: combining the received first PBCH payload with the first PBCH payload obtained based on applying the inverse of the fixed permutation to the second PBCH payload; and detecting the first encoded SFN based on the combination.

In some aspects, the method 700 further includes decoding the detected first encoded SFN to determine a first SFN of the set of SFNs. In some cases, the operations of this step refer to, or may be performed by, circuitry for decoding and/or code for decoding as described with reference to FIG. 9.

In some aspects, the first encoded SFN comprises k bits.

In some aspects, at least the first encoded SFN comprises a one-hot vector that indicates the first SFN of the set of SFNs, wherein the one-hot vector includes a plurality of different bit-positions; each bit-position of the plurality of different bit-positions corresponds to a different SFN of the set of SFNs; and to indicate the first SFN: the one-hot vector includes a bit having a bit-value of one within a bit-position, of the plurality of different bit-positions, corresponding to the first SFN; and the one-hot vector includes bits having bit-values of zero within bit-positions, of the plurality of different bit-positions, that do not correspond to the first SFN.

In some aspects, the one-hot vector has a length K that is equal to 2^{k}.

In some aspects, the one-hot vector has a length K that is not equal to 2^{k}.

In some aspects, at least the first encoded SFN comprises a one-hot complex vector that indicates the first SFN of the set of SFNs, wherein: the one-hot vector includes a plurality of different bit-positions; each bit-position of the plurality of different bit-positions corresponds to a different SFN of the set of SFNs; and to indicate the first SFN: the one-hot vector includes a bit having a non-zero bit-value within a bit-position, of the plurality of different bit-positions, corresponding to the first SFN; and the one-hot vector includes bits having bit-values of zero within bit-positions, of the plurality of different bit-positions, that do not correspond to the first SFN.

In some aspects, the one-hot complex vector has a length K that is equal to 2^{k-1}.

In some aspects, the one-hot complex vector has a length K that is not equal to 2^{k-1}.

In some aspects, at least the first encoded SFN comprises a particular orthogonal sequence, of a plurality of orthogonal sequences, that indicates the first SFN of the set of SFNs, wherein each orthogonal sequence of the plurality of orthogonal sequences corresponds to a different SFN of the set of SFNs.

In some aspects, each orthogonal sequence of the plurality of orthogonal sequences has a length K that is equal to 2^{k}.

In some aspects, each orthogonal sequence of the plurality of orthogonal sequences has a length K that is not equal to 2^{k}.

In some aspects, the particular orthogonal sequence comprises one of a binary phase shift keying (BPSK) sequence or a quadrature phase shift keying (QPSK) sequence.

In some aspects, the transform function comprises an identity function.

In some aspects, the permutation comprises one of: a cyclic shift; a fixed length-2^{k} dpermutation having a period of 2^{k}; or a permutation having a period smaller than 2^{k}.

In some aspects, the transformation function comprises one of: an inverse discrete Fourier transform (DFT) function; an inverse fast Fourier transform (IFFT) function; a Hadamard transform (HT); or a fast Hadamard transform (FHT).

In some aspects, the first SFN indicated by the first encoded SFN and the second SFN indicated by the second encoded SFN are consecutive SFNs.

In one aspect, method 700, or any aspect related to it, may be performed by an apparatus, such as communications device 900 of FIG. 9, which includes various components operable, configured, or adapted to perform the method 700. Communications device 900 is described below in further detail.

Note that FIG. 7 is just one example of a method, and other methods including fewer, additional, or alternative steps are possible consistent with this disclosure.

### Example Communications Device(s)

FIG. 8 depicts aspects of an example communications device 800. In some aspects, communications device 800 is a network entity, such as BS 102 of FIGS. 1 and 3, or a disaggregated base station as discussed with respect to FIG. 2.

The communications device 800 includes a processing system 805 coupled to the transceiver 855 (e.g., a transmitter and/or a receiver) and/or a network interface 865. The transceiver 855 is configured to transmit and receive signals for the communications device 800 via the antenna 860, such as the various signals as described herein. The network interface 865 is configured to obtain and send signals for the communications device 800 via communication link(s), such as a backhaul link, midhaul link, and/or fronthaul link as described herein, such as with respect to FIG. 2. The processing system 805 may be configured to perform processing functions for the communications device 800, including processing signals received and/or to be transmitted by the communications device 800.

The processing system 805 includes one or more processors 810. In various aspects, one or more processors 810 may be representative of one or more of receive processor 338, transmit processor 320, TX MIMO processor 330, and/or controller/processor 340, as described with respect to FIG. 3. The one or more processors 810 are coupled to a computer-readable medium/memory 830 via a bus 850. In certain aspects, the computer-readable medium/memory 830 is configured to store instructions (e.g., computer-executable code) that when executed by the one or more processors 810, cause the one or more processors 810 to perform the operations described with respect to FIG. 5A and/or the method 600 described with respect to FIG. 6, or any aspect related to it. Note that reference to a processor of communications device 800 performing a function may include one or more processors 810 of communications device 800 performing that function.

In the depicted example, the computer-readable medium/memory 830 stores code (e.g., executable instructions), such as code for obtaining 835, code for applying 840, and code for transmitting 845. Processing of the code for obtaining 835, code for applying 840, and code for transmitting 845 may cause the communications device 800 to perform the operations described with respect to FIG. 5A and/or the method 600 described with respect to FIG. 6, or any aspect related to it.

The one or more processors 810 include circuitry configured to implement (e.g., execute) the code stored in the computer-readable medium/memory 830, including circuitry such as circuitry for obtaining 815, circuitry for applying 820, and circuitry for transmitting 825. Processing with circuitry for obtaining 815, circuitry for applying 820, and circuitry for transmitting 825 may cause the communications device 800 to perform the operations described with respect to FIG. 5A and/or the method 600 described with respect to FIG. 6, or any aspect related to it.

Various components of the communications device 800 may provide means for performing the operations described with respect to FIG. 5A and/or the method 600 described with respect to FIG. 6, or any aspect related to it. Means for transmitting, sending or outputting for transmission may include transceivers 332 and/or antenna(s) 334 of the BS 102 illustrated in FIG. 3 and/or the transceiver 855 and the antenna 860 of the communications device 800 in FIG. 8. Means for receiving or obtaining may include transceivers 332 and/or antenna(s) 334 of the BS 102 illustrated in FIG. 3 and/or the transceiver 855 and the antenna 860 of the communications device 800 in FIG. 8.

FIG. 9 depicts aspects of an example communications device 900. In some aspects, communications device 900 is a user equipment, such as UE 104 described above with respect to FIGS. 1 and 3.

The communications device 900 includes a processing system 905 coupled to the transceiver 965 (e.g., a transmitter and/or a receiver). The transceiver 965 is configured to transmit and receive signals for the communications device 900 via the antenna 970, such as the various signals as described herein. The processing system 905 may be configured to perform processing functions for the communications device 900, including processing signals received and/or to be transmitted by the communications device 900.

The processing system 905 includes one or more processors 910. In various aspects, the one or more processors 910 may be representative of one or more of receive processor 358, transmit processor 364, TX MIMO processor 366, and/or controller/processor 380, as described with respect to FIG. 3. The one or more processors 910 are coupled to a computer-readable medium/memory 935 via a bus 960. In certain aspects, the computer-readable medium/memory 935 is configured to store instructions (e.g., computer-executable code) that when executed by the one or more processors 910, cause the one or more processors 910 to perform the operations described with respect to FIG. 5B and/or the method 700 described with respect to FIG. 7, or any aspect related to it. Note that reference to a processor performing a function of communications device 900 may include one or more processors 910 performing that function of communications device 900.

In the depicted example, computer-readable medium/memory 935 stores code (e.g., executable instructions), such as code for receiving 940, code for performing 945, code for applying 950, and code for decoding 955. Processing of the code for receiving 940, code for performing 945, code for applying 950, and code for decoding 955 may cause the communications device 900 to perform the operations described with respect to FIG. 5B and/or the method 700 described with respect to FIG. 7, or any aspect related to it.

The one or more processors 910 include circuitry configured to implement (e.g., execute) the code stored in the computer-readable medium/memory 935, including circuitry such as circuitry for receiving 915, circuitry for performing 920, circuitry for applying 925, and circuitry for decoding 930. Processing with circuitry for receiving 915, circuitry for performing 920, circuitry for applying 925, and circuitry for decoding 930 may cause the communications device 900 to perform the operations described with respect to FIG. 5B and/or the method 700 described with respect to FIG. 7, or any aspect related to it.

Various components of the communications device 900 may provide means for performing the operations described with respect to FIG. 5B and/or the method 700 described with respect to FIG. 7, or any aspect related to it. For example, means for transmitting, sending or outputting for transmission may include transceivers 354 and/or antenna(s) 352 of the UE 104 illustrated in FIG. 3 and/or the transceiver 965 and the antenna 970 of the communications device 900 in FIG. 9. Means for receiving or obtaining may include transceivers 354 and/or antenna(s) 352 of the UE 104 illustrated in FIG. 3 and/or the transceiver 965 and the antenna 970 of the communications device 900 in FIG. 9.

### Example Clauses

Implementation examples are described in the following numbered clauses:

Clause 1: A method for wireless communication by a network entity, comprising: obtaining a first physical broadcast channel (PBCH) payload including a first encoded system frame number (SFN) that indicates a first SFN of a set of SFNs, wherein the first PBCH payload is obtained based on a fixed permutation; applying a transform function to the first PBCH payload to convert the first PBCH payload to a transform domain; and transmitting the first PBCH payload after applying the transform function to the first PBCH payload.

Clause 2: The method of Clause 1, further comprising: applying the fixed permutation to the first PBCH payload to obtain a second PBCH payload including a second encoded SFN that indicates a second SFN of the set of SFNs; applying the transform function to the second PBCH payload to convert the second PBCH payload to the transform domain; and transmitting the second PBCH payload after applying the transform function to the second PBCH payload, wherein the first SFN indicated by the first encoded SFN and the second SFN indicated by the second encoded SFN are consecutive SFNs.

Clause 3: The method of any one of Clauses 1-2, wherein obtaining the first PBCH payload including the first encoded SFN comprises applying the fixed permutation to a second PBCH payload including a second encoded SFN, transmitted before the first PBCH payload, to obtain the first PBCH payload including the first encoded SFN.

Clause 4: The method of Clause 3, wherein the first encoded SFN comprises k bits.

Clause 5: The method of Clause 4, wherein the first encoded SFN comprises a one-hot vector that indicates the first SFN of the set of SFNs, wherein the one-hot vector includes a plurality of different bit-positions; each bit-position of the plurality of different bit-positions corresponds to a different SFN of the set of SFNs; and to indicate the first SFN: the one-hot vector includes a bit having a bit-value of one within a bit-position, of the plurality of different bit-positions, corresponding to the first SFN; and the one-hot vector includes bits having bit-values of zero within bit-positions, of the plurality of different bit-positions, that do not correspond to the first SFN.

Clause 6: The method of Clause 5, wherein the one-hot vector has a length K that is equal to 2^{k}.

Clause 7: The method of Clause 5, wherein the one-hot vector has a length K that is not equal to 2^{k}.

Clause 8: The method of Clause 4, wherein the first encoded SFN comprises a one-hot complex vector that indicates the first SFN of the set of SFNs, wherein: the one-hot complex vector includes a plurality of different bit-positions; each bit-position of the plurality of different bit-positions corresponds to a different SFN of the set of SFNs; and to indicate the first SFN: the one-hot complex vector includes a bit having a non-zero bit-value within a bit-position, of the plurality of different bit-positions, corresponding to the first SFN; and the one-hot complex vector includes bits having bit-values of zero within bit-positions, of the plurality of different bit-positions, that do not correspond to the first SFN.

Clause 9: The method of Clause 8, wherein the one-hot complex vector has a length K that is equal to 2^{k-1}.

Clause 10: The method of Clause 8, wherein the one-hot complex vector has a length K that is not equal to 2^{k-1}.

Clause 11: The method of Clause 4, wherein the first encoded SFN comprises a particular orthogonal sequence, of a plurality of orthogonal sequences, that indicates the first SFN of the set of SFNs, wherein each orthogonal sequence of the plurality of orthogonal sequences corresponds to a different SFN of the set of SFNs.

Clause 12: The method of Clause 11, wherein each orthogonal sequence of the plurality of orthogonal sequences has a length K that is equal to 2^{k}.

Clause 13: The method of Clause 11, wherein each orthogonal sequence of the plurality of orthogonal sequences has a length K that is not equal to 2^{k}.

Clause 14: The method of Clause 11, wherein the particular orthogonal sequence comprises one of a binary phase shift keying (BPSK) sequence or a quadrature phase shift keying (QPSK) sequence.

Clause 15: The method of Clause 11, wherein the transform function comprises an identity function.

Clause 16: The method of Clause 4, wherein the fixed permutation comprises one of: a cyclic shift; a fixed length-2^{k} permutation having a period of 2^{k}; or a permutation having a period smaller than 2^{k}.

Clause 17: The method of Clause 4, wherein the transform function comprises one of: an inverse discrete Fourier transform (IDFT) function; an inverse fast Fourier transform (IFFT) function; a Hadamard transform (HT); or a fast Hadamard transform (FHT).

Clause 18: A method for wireless communication by a user equipment (UE), comprising: receiving a first physical broadcast channel (PBCH) payload including a first encoded system frame number (SFN) that indicates a first SFN of a set of SFNs, wherein the first PBCH payload is based on a fixed permutation and a transform function; receiving a second PBCH payload including a second encoded SFN that indicates a second SFN of the set of SFNs, wherein the second PBCH payload is based on the first PBCH payload including the first encoded SFN, the fixed permutation, and the transform function; and performing a soft combining procedure to detect the first encoded SFN based on the first PBCH payload and the second PBCH payload.

Clause 19: The method of Clause 18, further comprising: applying an inverse of the transform function to the first PBCH payload; applying the inverse of the transform function to the second PBCH payload; and applying, after applying the inverse of the transform function to the second PBCH payload, an inverse of the fixed permutation to the second PBCH payload to obtain the first PBCH payload.

Clause 20: The method of Clause 19, wherein performing the soft combining procedure comprises: combining the received first PBCH payload with the first PBCH payload obtained based on applying the inverse of the fixed permutation to the second PBCH payload; and detecting the first encoded SFN based on the combination.

Clause 21: The method of Clause 20, further comprising decoding the detected first encoded SFN to determine a first SFN of the set of SFNs.

Clause 22: The method of Clause 21, wherein the first encoded SFN comprises k bits.

Clause 23: The method of Clause 22, wherein at least the first encoded SFN comprises a one-hot vector that indicates the first SFN of the set of SFNs, wherein the one-hot vector includes a plurality of different bit-positions; each bit-position of the plurality of different bit-positions corresponds to a different SFN of the set of SFNs; and to indicate the first SFN: the one-hot vector includes a bit having a bit-value of one within a bit-position, of the plurality of different bit-positions, corresponding to the first SFN; and the one-hot vector includes bits having bit-values of zero within bit-positions, of the plurality of different bit-positions, that do not correspond to the first SFN.

Clause 24: The method of Clause 23, wherein the one-hot vector has a length K that is equal to 2^{k}.

Clause 25: The method of Clause 23, wherein the one-hot vector has a length K that is not equal to 2^{k}.

Clause 26: The method of Clause 22, wherein at least the first encoded SFN comprises a one-hot complex vector that indicates the first SFN of the set of SFNs, wherein: the one-hot vector includes a plurality of different bit-positions; each bit-position of the plurality of different bit-positions corresponds to a different SFN of the set of SFNs; and to indicate the first SFN: the one-hot vector includes a bit having a non-zero bit-value within a bit-position, of the plurality of different bit-positions, corresponding to the first SFN; and the one-hot vector includes bits having bit-values of zero within bit-positions, of the plurality of different bit-positions, that do not correspond to the first SFN.

Clause 27: The method of Clause 26, wherein the one-hot complex vector has a length K that is equal to 2^{k-1}.

Clause 28: The method of Clause 26, wherein the one-hot complex vector has a length K that is not equal to 2^{k-1}.

Clause 29: The method of Clause 22, wherein at least the first encoded SFN comprises a particular orthogonal sequence, of a plurality of orthogonal sequences, that indicates the first SFN of the set of SFNs, wherein each orthogonal sequence of the plurality of orthogonal sequences corresponds to a different SFN of the set of SFNs.

Clause 30: The method of Clause 29, wherein each orthogonal sequence of the plurality of orthogonal sequences has a length K that is equal to 2^{k}.

Clause 31: The method of Clause 29, wherein each orthogonal sequence of the plurality of orthogonal sequences has a length K that is not equal to 2^{k}.

Clause 32: The method of Clause 29, wherein the particular orthogonal sequence comprises one of a binary phase shift keying (BPSK) sequence or a quadrature phase shift keying (QPSK) sequence.

Clause 33: The method of Clause 29, wherein the transform function comprises an identity function.

Clause 34: The method of Clause 22, wherein the permutation comprises one of: a cyclic shift; a fixed length-2^{k} permutation having a period of 2^{k}; or a permutation having a period smaller than 2^{k}.

Clause 35: The method of Clause 22, wherein the transformation function comprises one of: an inverse discrete Fourier transform (DFT) function; an inverse fast Fourier transform (IFFT) function; a Hadamard transform (HT); or a fast Hadamard transform (FHT).

Clause 36: The method of any one of Clauses 18-35, wherein the first SFN indicated by the first encoded SFN and the second SFN indicated by the second encoded SFN are consecutive SFNs.

Clause 37: An apparatus, comprising: at least one memory comprising executable instructions; and at least one processor configured to execute the executable instructions and cause the apparatus to perform a method in accordance with any combination of Clauses 1-36.

Clause 38: An apparatus, comprising means for performing a method in accordance with any combination of Clauses 1-36.

Clause 39: A non-transitory computer-readable medium comprising executable instructions that, when executed by at least one processor of an apparatus, cause the apparatus to perform a method in accordance with any combination of Clauses 1-36.

Clause 40: A computer program product embodied on a computer-readable storage medium comprising code for performing a method in accordance with any combination of Clauses 1-36.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

In some cases, rather than actually transmitting a signal, an apparatus (e.g., a wireless node or device) may have an interface to output the signal for transmission. For example, a processor may output a signal, via a bus interface, to a radio frequency (RF) front end for transmission. Accordingly, a means for outputting may include such an interface as an alternative (or in addition) to a transmitter or transceiver. Similarly, rather than actually receiving a signal, an apparatus (e.g., a wireless node or device) may have an interface to obtain a signal from another device. For example, a processor may obtain (or receive) a signal, via a bus interface, from an RF front end for reception. Accordingly, a means for obtaining may include such an interface as an alternative (or in addition) to a receiver or transceiver.

While the present disclosure may describe certain operations as being performed by one type of wireless node, the same or similar operations may also be performed by another type of wireless node. For example, operations performed by a user equipment (UE) may also (or instead) be performed by a network entity (e.g., a base station or unit of a disaggregated base station). Similarly, operations performed by a network entity may also (or instead) be performed by a UE.

Further, while the present disclosure may describe certain types of communications between different types of wireless nodes (e.g., between a network entity and a UE), the same or similar types of communications may occur between same types of wireless nodes (e.g., between network entities or between UEs, in a peer-to-peer scenario). Further, communications may occur in reverse order than described.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112 (f) unless the element is expressly recited using the phrase “means for”. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A network entity, comprising:
at least one memory comprising executable instructions; and
one or more processors individually or collectively configured to execute the executable instructions to cause the network entity to:
obtain a first physical broadcast channel (PBCH) payload including a first encoded system frame number (SFN) that indicates a first SFN of a set of SFNs, wherein the first PBCH payload is obtained based on a fixed permutation;
apply a transform function to the first PBCH payload to convert the first PBCH payload to a transform domain; and
transmit the first PBCH payload after applying the transform function to the first PBCH payload.

2. The network entity of claim 1, wherein the one or more processors are further configured to cause the network entity to:
apply the fixed permutation to the first PBCH payload to obtain a second PBCH payload including a second encoded SFN that indicates a second SFN of the set of SFNs;
apply the transform function to the second PBCH payload to convert the second PBCH payload to the transform domain; and
transmit the second PBCH payload after applying the transform function to the second PBCH payload, wherein the first SFN indicated by the first encoded SFN and the second SFN indicated by the second encoded SFN are consecutive SFNs.

3. The network entity of claim 1, wherein, to obtain the first PBCH payload including the first encoded SFN, the one or more processors are configured to cause the network entity to apply the fixed permutation to a second PBCH payload including a second encoded SFN, transmitted before the first PBCH payload, to obtain the first PBCH payload including the first encoded SFN.

4. The network entity of claim 3, wherein the first encoded SFN comprises k bits.

5. The network entity of claim 4, wherein the first encoded SFN comprises a one-hot vector that indicates the first SFN of the set of SFNs, wherein the one-hot vector includes a plurality of different bit-positions;
each bit-position of the plurality of different bit-positions corresponds to a different SFN of the set of SFNs; and
to indicate the first SFN:
the one-hot vector includes a bit having a bit-value of one within a bit-position, of the plurality of different bit-positions, corresponding to the first SFN; and
the one-hot vector includes bits having bit-values of zero within bit-positions, of the plurality of different bit-positions, that do not correspond to the first SFN.

6. The network entity of claim 5, wherein the one-hot vector has a length K that is equal to 2^{k}.

7. The network entity of claim 5, wherein the one-hot vector has a length K that is not equal to 2^{k}.

8. The network entity of claim 4, wherein the first encoded SFN comprises a one-hot complex vector that indicates the first SFN of the set of SFNs, wherein:
the one-hot complex vector includes a plurality of different bit-positions;
each bit-position of the plurality of different bit-positions corresponds to a different SFN of the set of SFNs; and
to indicate the first SFN:
the one-hot complex vector includes a bit having a non-zero bit-value within a bit-position, of the plurality of different bit-positions, corresponding to the first SFN; and
the one-hot complex vector includes bits having bit-values of zero within bit-positions, of the plurality of different bit-positions, that do not correspond to the first SFN.

9. The network entity of claim 8, wherein the one-hot complex vector has a length K that is equal to 2^{k-1}.

10. The network entity of claim 8, wherein the one-hot complex vector has a length K that is not equal to 2^{k-1}.

11. The network entity of claim 4, wherein the first encoded SFN comprises a particular orthogonal sequence, of a plurality of orthogonal sequences, that indicates the first SFN of the set of SFNs, wherein each orthogonal sequence of the plurality of orthogonal sequences corresponds to a different SFN of the set of SFNs.

12. The network entity of claim 11, wherein each orthogonal sequence of the plurality of orthogonal sequences has a length K that is equal to 2^{k}.

13. The network entity of claim 11, wherein each orthogonal sequence of the plurality of orthogonal sequences has a length K that is not equal to 2^{k}.

14. The network entity of claim 11, wherein the particular orthogonal sequence comprises one of a binary phase shift keying (BPSK) sequence or a quadrature phase shift keying (QPSK) sequence.

15. The network entity of claim 4, wherein:
the fixed permutation comprises one of:
a cyclic shift;
a fixed length-2^{k} permutation having a period of 2^{k}; or
a permutation having a period smaller than 2^{k}; and
the transform function comprises one of:
an inverse discrete Fourier transform (IDFT) function;
an inverse fast Fourier transform (IFFT) function;
a Hadamard transform (HT);
a fast Hadamard transform (FHT); or
an identity function.

16. A user equipment (UE), comprising:
at least one memory comprising executable instructions; and
one or more processors individually or collectively configured to execute the executable instructions to cause the UE to:
receive a first physical broadcast channel (PBCH) payload including a first encoded system frame number (SFN) that indicates a first SFN of a set of SFNs, wherein the first PBCH payload is based on a fixed permutation and a transform function;
receive a second PBCH payload including a second encoded SFN that indicates a second SFN of the set of SFNs, wherein the second PBCH payload is based on the first PBCH payload including the first encoded SFN, the fixed permutation, and the transform function; and
perform a soft combining procedure to detect the first encoded SFN based on the first PBCH payload and the second PBCH payload.

17. The UE of claim 16, where in the one or more processors are further configured to cause the UE to:
apply an inverse of the transform function to the first PBCH payload;
apply the inverse of the transform function to the second PBCH payload; and
after applying the inverse of the transform function to the second PBCH payload, apply an inverse of the fixed permutation to the second PBCH payload to obtain the first PBCH payload.

18. The UE of claim 17, wherein, to perform the soft combining procedure, the one or more processors are configured to cause the UE to:
combine the received first PBCH payload with the first PBCH payload obtained based on applying the inverse of the fixed permutation to the second PBCH payload; and
detect the first encoded SFN based on the combination.

19. The UE of claim 18, wherein the one or more processors are further configured to cause the UE to decode the detected first encoded SFN to determine a first SFN of the set of SFNs.

20. A method for wireless communication by a network entity, comprising:
obtaining a first physical broadcast channel (PBCH) payload including a first encoded system frame number (SFN) that indicates a first SFN of a set of SFNs, wherein the first PBCH payload is obtained based on a fixed permutation;
applying a transform function to the first PBCH payload to convert the first PBCH payload to a transform domain; and
transmitting the first PBCH payload after applying the transform function to the first PBCH payload.
